(19) United States
(12) Patent Application Publication
(10) Pub. No.: US 2012/0119326 A1
(43) Pub. Date: May 17, 2012

(54) CAPACITOR AND SEMICONDUCTOR DEVICE

(75) Inventors: Tsuyoshi Sugisaki, Yokohama (JP); Masatoshi Fukuda, Yokohama (JP)

(73) Assignee: FUJITSU SEMICONDUCTOR LIMITED, Yokohama-shi (JP)

(21) Appl. No.: 13/207,728

(22) Filed: Aug. 11, 2011

(30) Foreign Application Priority Data
Nov. 17, 2010 (JP) 2010-256663

(51) Int. Cl. H01L 29/92; H01G 4/005

(52) U.S. Cl. 257/532; 361/303; 257/E29.343

(57) ABSTRACT

A capacitor includes first electrode patterns and second electrode patterns disposed alternately on a plane, each of the first electrode patterns having a linear shape and extending in a first direction from a first end to a third end with a first length, each of the second electrodes having a linear shape and extending in said first direction from a second end to a fourth end with a second length shorter than the first length, a first wiring pattern supplying a first voltage to the first electrode patterns by first via-plugs, and a second wiring pattern supplying a second voltage to the second electrode patterns by second via-plugs, wherein the first end of the first electrode pattern extends beyond the second end of the second electrode pattern and the third end of the first electrode pattern extends beyond the fourth end of said the electrode.

### CROSS-REFERENCE TO RELATED APPLICATIONS

The present application is based upon and claims the benefit of priority from the prior Japanese Patent Application No. 2010-256663 filed on Nov. 17, 2010, with the Japanese Patent Office, the entire contents of which are incorporated herein by reference.

### FIELD

The embodiments described herein relate to a capacitor and a semiconductor device having such a capacitor.

### BACKGROUND

In high-frequency circuits or in the circuits handling analog signals, there is a demand for a capacitor having excellent voltage characteristics or excellent frequency characteristics, and thus, there has been used MIM (metal-insulator-metal) capacitors in which metal electrode patterns are embedded in an insulation film or MOM (metal-oxide-metal) capacitors in which a metal electrode pattern is embedded in an oxide film. In the explanations below, MOM capacitors are included in MIM capacitors.

### RELATED-ART DOCUMENTS

### Patent Document

[Patent Document 1] Japanese Laid-Open Patent Application 2006-303220
[Patent Document 2] Japanese Laid-Open Patent Application 11-168182
[Patent Document 3] Japanese Laid-Open Patent Application 2002-124575
[Patent Reference 4] Japanese Laid-Open Patent Application 2001-127247
[Patent Reference 5] Japanese Laid-Open Patent Application 2006-128164
[Patent Reference 6] U.S. Pat. No. 4,424,552
[Patent Reference 7] U.S. Pat. No. 6,297,524
[Patent Reference 8] U.S. Pat. No. 6,822,312
[Patent Reference 9] U.S. Pat. No. 5,978,206
[Patent Reference 10] U.S. Pat. No. 6,635,916
[Patent Reference 11] U.S. Pat. No. 5,583,359
[Patent Reference 12] U.S. Pat. No. 6,737,698

### SUMMARY

In an aspect, a capacitor comprises: first electrode patterns and second electrode patterns disposed alternately on a plane, each of said first electrode patterns having a linear shape and extending in a first direction from a first end to a third end with a first length, each of said second electrodes having a linear shape and extending in said first direction from a second end to a fourth end with a second length shorter than said first length; a first wiring pattern supplying a first voltage to said first electrode patterns by first via-plugs: a second wiring pattern supplying a second voltage to said second electrode patterns by second via-plugs, said capacitor having a construction that, when said first and second electrode patterns are compared in said first direction, said first end of said first electrode pattern extends beyond said second end of said second electrode pattern, and said third end of said first electrode pattern extends beyond said fourth end of said second electrode.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1A is a plan view diagram representing an MIM capacitor according to a first embodiment;

FIG. 1B is a cross-sectional diagram of the MIM capacitor of FIG. 1A taken along a line A-A′ of FIG. 1A;

FIG. 1C is a cross-sectional diagram of the MIM capacitor of FIG. 1A taken along a line B-B′ of FIG. 1A;

FIG. 1D is a cross-sectional diagram of the MIM capacitor of FIG. 1A taken along a line C-C′ of FIG. 1A;

FIG. 1E is a cross-sectional diagram of the MIM capacitor of FIG. 1A taken along a line D-D′ of FIG. 1A;

FIG. 2 is a plan view diagram representing the array of the electrode patterns in FIG. 1A;

FIG. 3A is a diagram explaining the function of shielding attained by the array of electrode patterns of FIG. 2;

FIG. 3B is a diagram explaining the leakage of electric field in the array of electrode patterns for an MIM capacitor according to a comparative example;

FIG. 4 a diagram representing the construction of the MIM capacitor according to the comparative example;

FIG. 5A is a diagram explaining the problems associated with the MIM capacitor of the comparative example;

FIG. 5B is a diagram representing a part of FIG. 5A with enlarged scale;

FIG. 6 is a graph representing the results of the simulation for evaluating the shielding effect in the construction of FIG. 3A;

FIG. 7 is a plan view diagram representing the model structure and parameters used in the simulation of FIG. 6;

FIG. 8 is a plan view diagram representing the model structure and parameters used in the simulation of FIG. 6 for the evaluation of the comparative example;

FIG. 9A is a diagram representing the results of the electric field distribution obtained by the simulation for the electrode structure of the first embodiment;

FIG. 9B is a plan view diagram representing the array of the electrode patterns used for the simulation if FIG. 9A;

FIG. 10A is a diagram representing the results of the electric field distribution obtained by the simulation for the electrode structure of the comparative example;

FIG. 10B is a plan view diagram representing the array of the electrode patterns used for the simulation if FIG. 10A;

FIG. 11 is a plan view diagram representing an MIM capacitor according to a second embodiment;

FIG. 12 is a plan view diagram representing the array of the electrode patterns in FIG. 11;

FIG. 13 is a plan view diagram representing an MIM capacitor according to a modification of the second embodiment;

FIG. 14 is a plan view diagram representing the array of the electrode patterns in the modification of FIG. 13;

FIG. 15A is a plan view diagram representing an MIM capacitor according to a third embodiment;

FIG. 15B is a cross-sectional diagram of the MIM capacitor of FIG. 15A taken along a line A-A′ of FIG. 15A;

FIG. 15C is a cross-sectional diagram of the MIM capacitor of FIG. 15A taken along a line B-B′ of FIG. 15A;

FIG. 15D is a cross-sectional diagram of the MIM capacitor of FIG. 15A taken along a line C-C′ of FIG. 15A;

FIG. 16A is a plan view diagram representing an MIM capacitor according to a fourth embodiment;

FIG. 16B is a cross-sectional diagram of the MIM capacitor of FIG. 16A taken along a line A-A′ of FIG. 16A;

FIG. 16C is a cross-sectional diagram of the MIM capacitor of FIG. 16A taken along a line B-B′ of FIG. 16A;

FIG. 17A is a plan view diagram representing an MIM capacitor according to a fifth embodiment;

FIG. 17B is a cross-sectional diagram of the MIM capacitor of FIG. 17A taken along a line A-A′ of FIG. 17A;

FIG. 17C is a cross-sectional diagram of the MIM capacitor of FIG. 17A taken along a line B-B′ of FIG. 17A;

FIG. 18A is a plan view diagram representing an MIM capacitor according to a sixth embodiment;

FIG. 18B is a cross-sectional diagram of the MIM capacitor of FIG. 18A taken along a line A-A′ of FIG. 18A;

FIG. 18C is a cross-sectional diagram of the MIM capacitor of FIG. 18A taken along a line B-B′ of FIG. 18A;

FIG. 18D is a cross-sectional diagram of the MIM capacitor of FIG. 18A taken along a line C-C′ of FIG. 18A;

FIG. 18E is a plan view diagram representing the array of the wiring pattern and the ground pattern of the uppermost layer in the structure of FIG. 18A;

FIG. 18F is a plan view diagram representing the array of the electrode patterns in the structure of FIG. 18A;

FIG. 18G is a plan view diagram representing the array of the ground pattern in the lowermost layer of the structure of FIG. 18A;

FIG. 18H is a plan view diagram representing the function of the ground pattern in the structure of FIG. 18A;

FIG. 18I is a plan view diagram representing the result of simulation with regard to the function of the ground pattern in the structure of FIG. 18A;

FIG. 18J is a diagram representing an equivalent circuit diagram of the MIM capacitor of FIG. 18A;

FIG. 19A is a plan view diagram representing an MIM capacitor according to a seventh embodiment;

FIG. 19B is a cross-sectional diagram of the MIM capacitor of FIG. 19A taken along a line A-A′ of FIG. 19A;

FIG. 19C is a cross-sectional diagram of the MIM capacitor of FIG. 19A taken along a line B-B′ of FIG. 19A;

FIG. 19D is a cross-sectional diagram of the MIM capacitor of FIG. 19A taken along a line C-C′ of FIG. 19A;

FIG. 19E is a plan view diagram representing the array of the ground pattern in the lowermost layer of the structure of FIG. 19A;

FIG. 20 is a cross-sectional diagram representing the construction of a semiconductor device according to an eighth embodiment in which the MIM capacitor is integrated:

FIG. 21 is a circuit diagram representing an A/D converter according to a ninth embodiment constructed by using the semiconductor device of FIG. 20.

### DESCRIPTION OF EMBODIMENTS

### First Embodiment

Generally, the MIM capacitors for integration with a semiconductor integrated circuit take the form of comb-shaped electrode patterns or parallel electrode patterns of the same length surrounded by a ground pattern. Reference should be made to Patent References 1-12 noted before.

On the other hand, in the applications such as low-pass filters, high-frequency circuits, A/D converters, and the like, there is a demand for an MIM capacitor of particularly high precision. Further there is a desire to integrate such an MIM capacitor into a semiconductor device.

In order to form an MIM capacitor with high precision, it is necessary to form a large number of electrode patterns with high precision. This means that it is necessary to form the electrode patterns with sufficient mutual separation for avoiding proximity effect at the time of exposure. However, the high-precision MIM capacitor thus formed has a drawback in that, when the MIM capacitor is formed to have the desired capacitance, the MIM capacitor may occupy a large area. Meanwhile, an MIM capacitor integrated into a semiconductor integrated circuit is also subjected to the stringent requirement of miniaturization, and thus, it has been difficult for MIM capacitors to have high precision capacitance.

For example, in the case of an MIM capacitor having the comb-shaped electrodes, there are formed a number of electrode fingers supplied with a first voltage such that the electrode fingers extend parallel with each other from a common ground electrode pattern, and there are also formed different electrode fingers supplied with a second voltage such that the different electrode fingers extend, from another common electrode pattern supplied with the second voltage, within the gaps formed between the electrode fingers that are supplied with the first voltage. This means that, when the area of the MIM capacitor as a whole is reduced, there arises a situation that the tip end of the electrode fingers approaches to the common electrode pattern opposing thereto. Thus, when such a pattern is formed by photolithography, there may be caused the problem that the tip end of the electrode fingers and the common electrode pattern opposing thereto may no longer be resolved optically because of the optical proximity effect. While it is possible to compensate for the optical proximity effect to some extent and separate the two patterns from each other, the edges of the electrode fingers and the common electrode pattern thus obtained may still be undulated and there arises a problem that the capacitance cannot be determined with desired high precision. This problem appears particularly conspicuous when the distance between the tip end of the electrode fingers and the opposing common electrode pattern has been reduced and become nearly equal to the wavelength of the light used for exposure, such as 248 nm in the case of using a KrF excimer for the exposure optical source or 193 nm in the case of using an ArF excimer laser for the exposure optical source.

Further, in the type of the MIM capacitors having the construction in which a number of electrode patterns of the same length are disposed repeatedly in parallel, it is necessary to provide an electrical shield by surrounding the entire MIM capacitor with a ground pattern. However, in such a construction, the tip end of the electrode pattern supplied with a signal voltage comes close to the opposing ground pattern when the miniaturization is applied, and again, there arises the problem that resolution becomes difficult at the time of the photographic process. In this case, too, it is possible to separate the both patterns by carrying out the proximity effect compensation correction. However, even after such a correction, the edges of the individual electrode patterns extending parallel and the edges of the ground pattern surrounding the parallel electrode patterns may be undulated. Thus, it becomes difficult to determine the capacitance with sufficient precision.

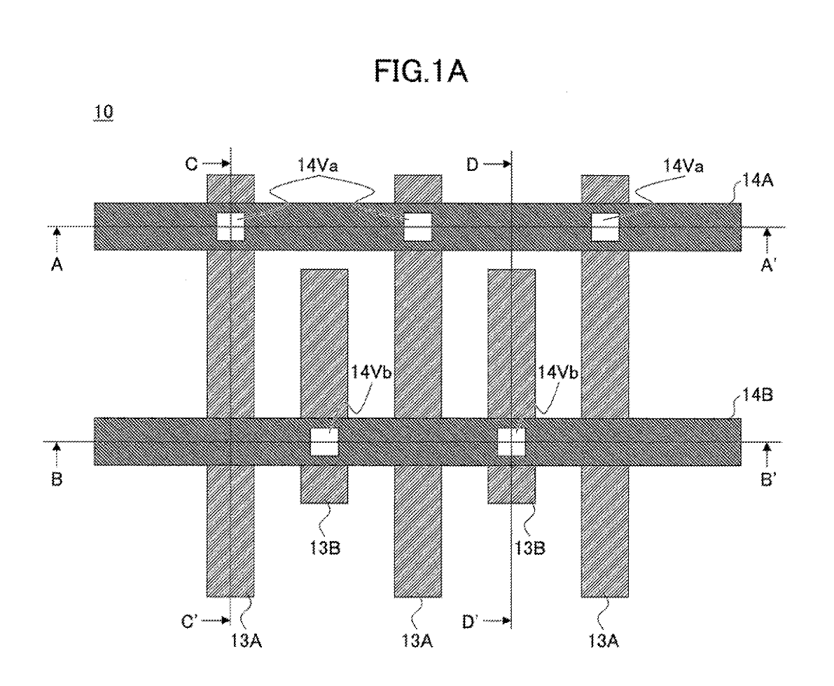

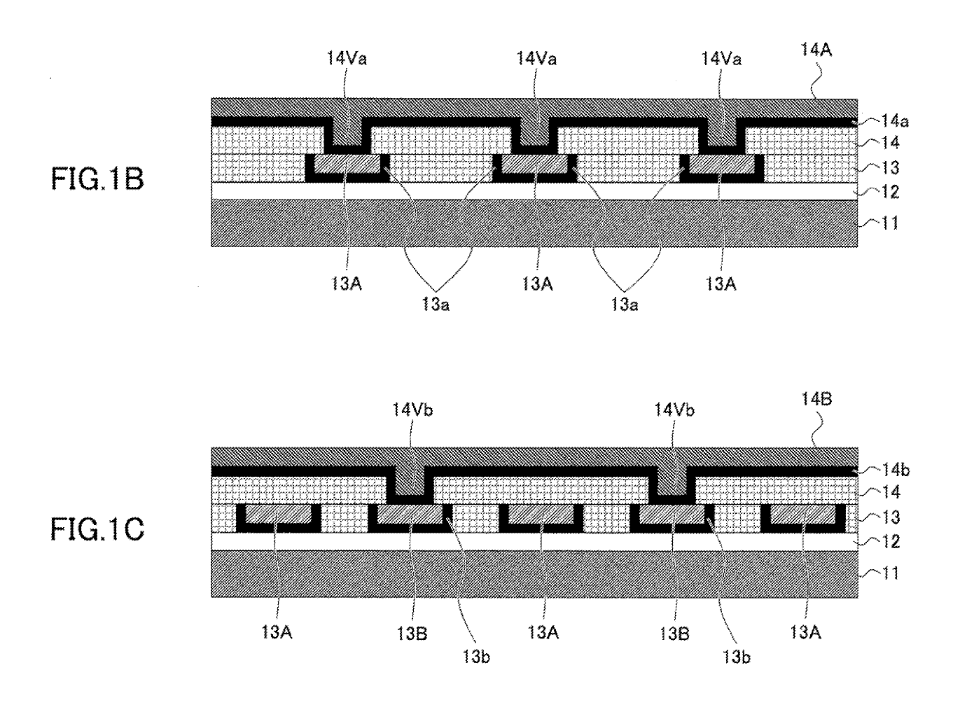

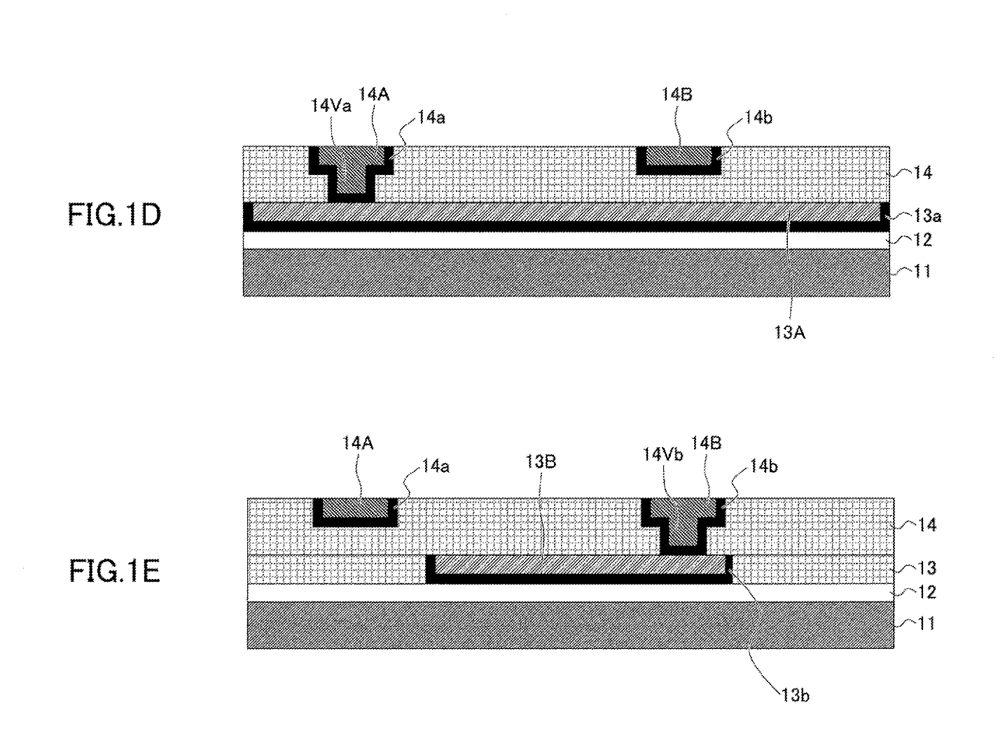

FIG. 1A is a plan view diagram representing the construction of an MIM capacitor 10 according to a first embodiment, FIG. 1B is a cross-sectional diagram of the MIM capacitor 10 of FIG. 1A taken along a line A-A′ in FIG. 1A, FIG. 1C is a cross-sectional diagram of the MIM capacitor 10 of FIG. 1A taken along a line B-B′ in FIG. 1A, FIG. 1D is a cross-sectional diagram of the MIM capacitor 10 of FIG. 1A taken along a line C-C′ in FIG. 1A, and FIG. 1E is a cross-sectional diagram representing the MIM capacitor 10 of FIG. 1A taken along a line D-D′ in FIG. 1A.

Referring to FIGS. 1A-1E, the MIM capacitor 10 includes first electrode patterns 13A of a linear shape and second electrode patterns 13B of a linear shape embedded generally parallel with each other and alternately in an interlayer insulation film 13 of silicon oxide or low-K dielectric having a specific dielectric constant smaller than that of silicon oxide, such as an SiOC film, an SiOCH film, an organic insulation film, and the like, wherein the interlayer insulation film 13 is formed over a silicon substrate 11 via a thermal oxide film 12.

As can be seen from the cross-sectional diagram of FIG. 1B and FIG. 1D, the first electrode patterns 13A are formed in the interlayer insulation film 13 by a damascene process via a barrier metal film 13a. Thus, the first electrode patterns 13A have a planarized surface coincident to the surface of the interlayer insulation film 13. Further, as can be seen from the cross-sectional diagrams of FIG. 1C and FIG. 1D, the second electrode patterns 13B are also formed in the interlayer insulation film 13 by a damascene process via a barrier metal film 13b and have a planarized surface coincident to the surface of the interlayer insulation film 13.

Further, a similar interlayer insulation film 14 is formed on the interlayer insulation film 13, and a first wiring pattern 14A is formed in the interlayer insulation film 14 also by a damascene process so as to intersect the first electrode patterns when viewed from the direction perpendicular to a principal surface of the silicon substrate 11, wherein the first wiring pattern 14A is connected electrically to the respective electrode patterns 13A that intersect the first wiring pattern 14A by respective via plugs 14Va. Similarly, in the interlayer insulation film 14, there is formed a second wiring pattern 14B also by a damascene process so as to intersect the second electrode patterns 13B when viewed in the direction perpendicular to the principal surface of the silicon substrate 11, wherein the wiring pattern 14B is connected electrically to the respective electrode patterns 13B intersecting thereto by via-plugs 14Vb.

Thus, by supplying a first voltage, such as a ground voltage, to the electrode patterns 13A via the wiring pattern 14A and the via-plugs 14Va and by supplying a second voltage, such as a signal voltage, to the electrode patterns 13B via the wiring pattern 14B and the via-plugs 14Vb, there is formed a desired capacitance in the MIM capacitor 10 corresponding to the capacitance formed between the electrode patterns 13A and the electrode patterns 13B.

As can be seen from the cross-sectional diagram of FIG. 1B through FIG. 1E, the first electrode patterns 13A, too, are formed in the interlayer insulation film 14 by a damascene process via a barrier metal film 14a. Thus, the first electrode patterns 14A have a planarized surface coincident to the surface of the interlayer insulation film 14. Further, the second wiring pattern 14B is also formed by a damascene process in the interlayer insulation film 14 via a barrier metal film 14b and has a planarized surface coincident to the surface of the interlayer insulation film 14.

The first and second electrode patterns 13A and 13B and the first and second wiring patterns 14A and 14B may be formed by copper for example. In this case, it is possible to form the via-plugs 14Va and 14Vb by an ordinary dual damascene process. The barrier metal films 13a and 13b and the barrier metal films 14a and 14b may be formed by an ordinary Ti film or Ta film or in the form of a Ti/TiN stacked film or Ta/TaN stacked film.

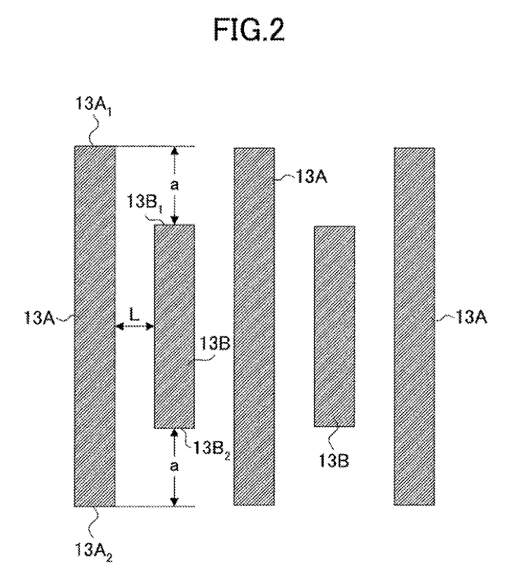

FIG. 2 is a plan view diagram representing only the first electrode patterns 13A and the second electrode patterns 13B in the MIM capacitor 10.

Comparing a first electrode pattern 13A and a second electrode pattern 13B adjacent thereto in the plan view diagram of FIG. 2, it can be seen that both of the first and second electrode patterns 13A and 13B extend in the upward direction of the sheet of the illustration from an end 13A₂ to an end 13A₁ and from an end 13B₂ to an end 13B₁, respectively, wherein the first end 13A₁ of the first electrode pattern 13A extends beyond the first end 13B₁ of the second electrode pattern 13B by a distance a and the second end 13A₂ of the first electrode pattern 13A opposite to the first end 13A₁ extends beyond the second end 13B₂ of the second electrode pattern 13B opposite to the second end 13A₂. In the present embodiment, as will be described below, the projecting distance a is set to be about three times of more, preferably about 3.6 times or more than a separation L between the electrode pattern 13A and the electrode pattern 13B.

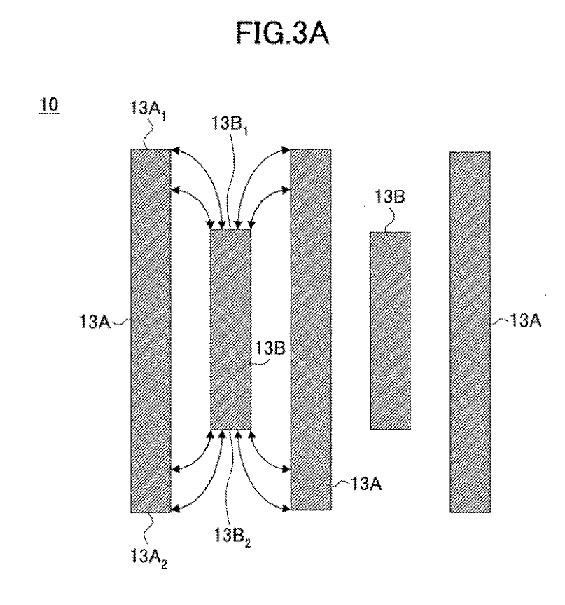

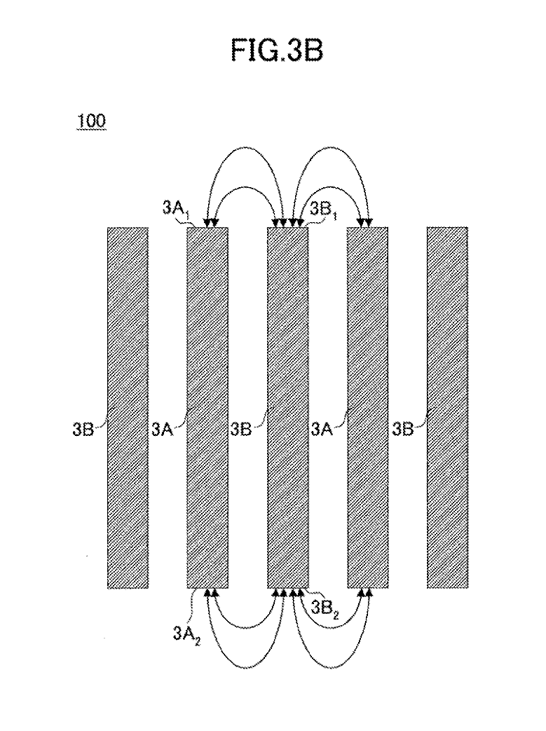

By causing the first end 13A₁ of the first electrode pattern 13A to extend beyond the first end 13B₁ of the second electrode pattern 13B by the foregoing distance a and by causing the second end 13A₂ of the first electrode pattern 13A to extend beyond the second end 13B₂ of the second electrode pattern 13B by the distance a, and by applying the first voltage to the first electrode patterns 13A and the second voltage to the second electrode patterns 13B, it becomes possible, as depicted in FIG. 3A, to terminate substantially entirety of the electric lines of force exiting from the first end 13A₁ of the first electrode pattern 13A by the first end 13B₁ of the second electrode pattern 13B and further terminate substantially the entirety of the electric lines of force exiting from the first end 13B₁ of the second electrode pattern 13B by the first end 13A₁ of the first electrode pattern 13A. Similarly, it is possible to terminate substantially the entirety of the electric lines of force exiting from the second end 13A₂ of the first electrode pattern 13A by the second end 13B₂ of the second electrode pattern 13B and further it is possible to terminate substantially the electric lines of force exiting from the second end 13B₂ of the second electrode pattern 13B by the second end 13A₂ of the first electrode pattern 13A. As a result, with the MIM capacitor 10 of the present embodiment, there occurs no leakage of electric field outside the region occupied by the MIM capacitor, more specifically, the region defined by the first end 13A₁ and the second end 13A₂ of the first electrode patterns 13A. Thus, there is no need of forming a pattern surrounding the array of the electrode patterns 13A and 13B for the purpose of electrostatic shielding.

In contrast, in the case of an MIM capacitor 100 according to a comparative example of the present embodiment, in which electrode patterns 3A and 3B of the same length are disposed alternately and in parallel as depicted in FIG. 3B, it can be seen that, with application of the first voltage to the first electrode patterns 3A and the second voltage to the electrode patterns 3B, the electric lines of force connecting an end 3A₁ or 3A₂ of the electrode pattern 3A to corresponding end 3B₁ or 3B₂ of the electrode pattern 3B extend beyond the respective ends of the electrode patterns 3A and 3B, and thus, beyond the area where the array of the electrode patterns 3A and 3B are formed.

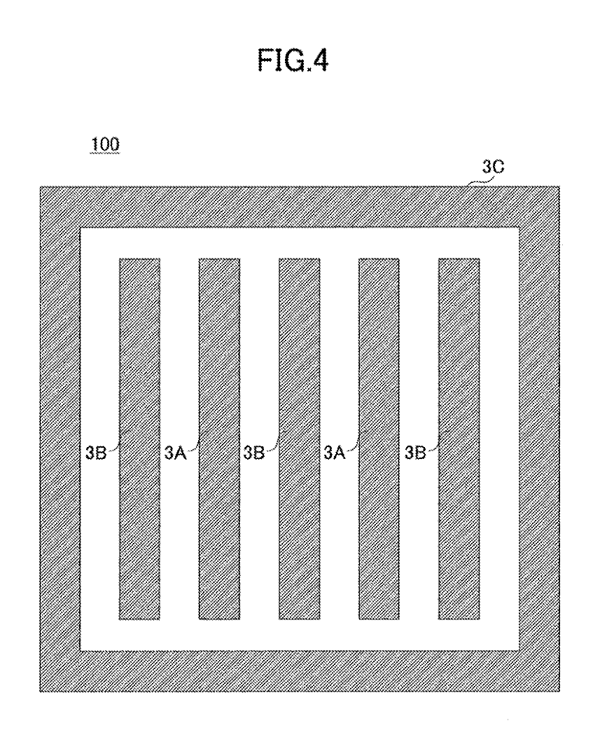

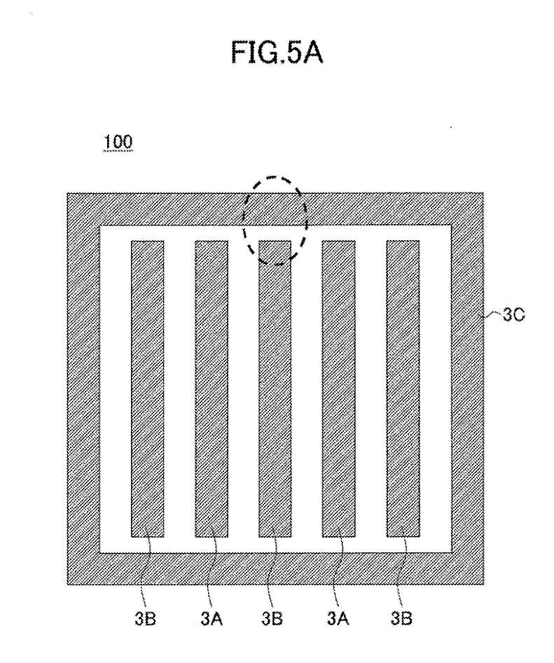

Thus, with the MIM capacitor 100 of to the comparative example of the present embodiment having the construction of FIG. 3B, there is a need of providing a ground pattern 3C for the purpose of electrostatic shielding so as to surround the array of the electrodes 3A and 3B as depicted in FIG. 4.

However, with the MIM capacitor 100 of the comparative example, there arises the problem, as a result of surrounding the electrode patterns 3A and 3B by the ground pattern 3C, that the area occupied by the MIM capacitor 100 is increased. Further, there can arise the problem, when the MIM capacitor 100 is miniaturized, that the tip end of the electrode patterns 3A and 3B approaches the ground pattern and the precision of the electrode patterns 3A and 3B is deteriorated.

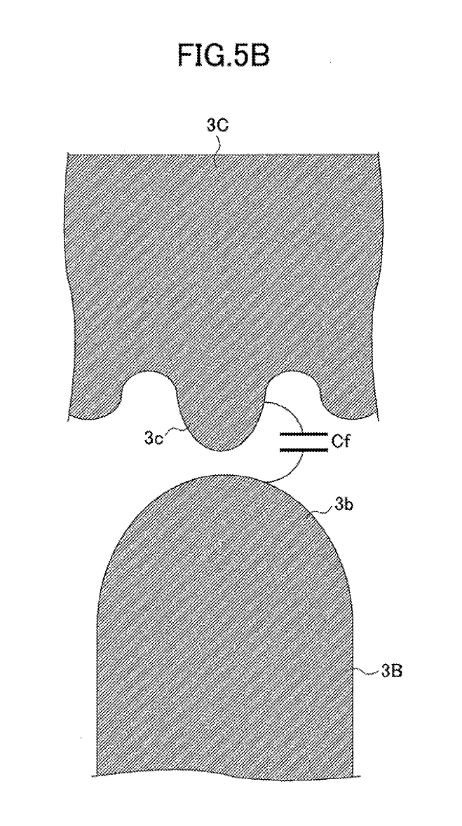

FIG. 5B is an enlarged view of the portion of FIG. 5A surrounded by a broken line.

Referring to FIG. 5B, it can be seen that the tip end of the electrode pattern 3B close to the ground pattern 3C forms an extension part 3b extending toward the electrode pattern 3C at the time of exposure as a result of optical proximity effect. Further, it can be seen that the part of the ground pattern 3C opposing the electrode pattern 3B has an undulating edge including an extension part 3c extending toward the electrode pattern 3B as a result of the optical proximity effect at the time of the exposure.

In the depicted example, the electrode patterns 3A-3B and the ground pattern 3C can be separated by applying a correction to the optical proximity effect by using a phase shift mask at the time of the exposure. However, there still arises the case in which the extension part 3b and the extension part 3c comes close with each other and form a parasitic capacitance Cf, which is not controlled satisfactorily. The MIM capacitor having such a parasitic capacitance may not be used for the applications where the requirement for the voltage characteristics and the frequency characteristics are stringent.

A similar problem may be caused also in the case of the MIM capacitors having a comb-shaped electrode in which an opposing electrode pattern extends in the proximity of the tip end of the electrode fingers when miniaturization is applied.

In contrast, with the MIM capacitor 10 of the present embodiment, which uses the electrode patterns 13A and 13B of linear shape with different lengths as depicted in FIG. 2, there is no need of disposing other electrode pattern in the proximity of the tip end part of the electrode patterns, and the problem of deformation of the electrode patterns by the proximity effect is less likely to occur even when the entirety of the MIM capacitor 10 is miniaturized. Thus, with the MIM capacitor 10 of the present embodiment, the electrode patterns 13A and 13B are formed with high precision, and it becomes possible to provide high precision capacitance.

Further, with the MIM capacitor 10 of the present embodiment, the wiring patterns 14A and 14B are formed in the wiring layer different from the wiring layer in which the electrode patterns 13A and 13B are formed as depicted in FIGS. 1A-1E such that the wiring patterns 14A and 14B are connected to the electrode patterns 13A and 13B with respective via-plugs 14Va and 14Vb, there occurs no such formation of the patterns that may cause proximity effect in the tip end part of the electrode patterns 13A and 13B in the wiring layer of the electrode patterns 13A and 13B.

In the construction of FIGS. 1A-1E, it is obvious to modify such that the electrode patterns 13A and 13B are disposed in the upper layer and the wiring patterns 14A and 14B are disposed in the lower layer, or one of the wiring patterns 14A and 14B is disposed below the electrode patterns 13A and 13B and the other of the wiring pattern is disposed above the electrode patterns 13A and 13B.

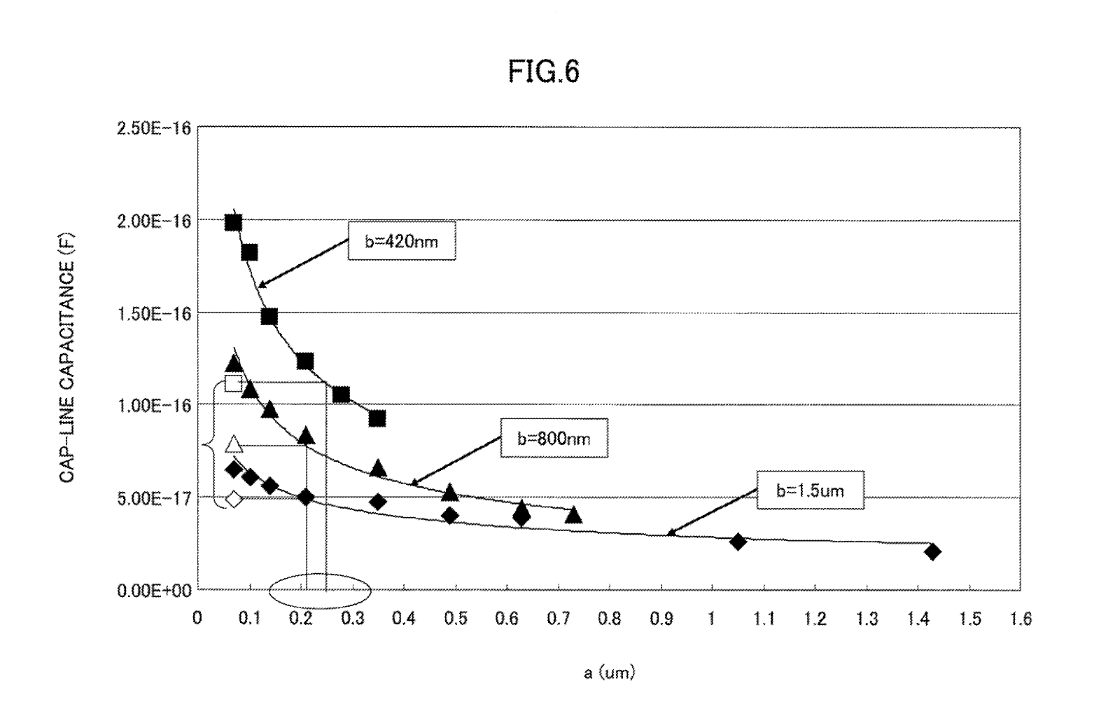

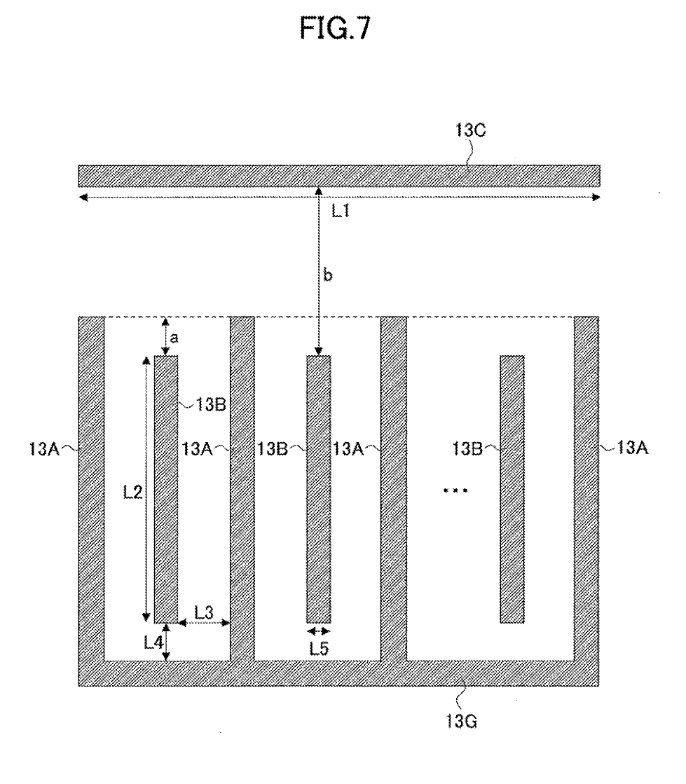

FIG. 6 is a diagram representing the result of the investigation made by simulation for the MIM capacitor 10 of the present embodiment about the leakage of the electric field from the MIM capacitor 10 while changing the extending distance a of FIG. 2 variously. It should be noted that the simulation of FIG. 6 is carried out for a model capacitor 10A of FIG. 7.

Referring to the model capacitor 10A of FIG. 7, the electrode patterns 13B each having a length L₂ of 2.5 μm are repeated for 99 times and the electrode patterns 13A are repeated for 100 times. At one side of the model capacitor 10A, there is formed a wiring pattern 13C of a length L₁ of 23.81 μm as a model of external wiring pattern such that the wiring pattern 13C opposes each of the electrode patterns 13A and 13B. It should be noted that each of the electrode patterns 13A and 13B has a width L₅ of 70 nm, wherein the electrode patterns 13A and 13B are repeated with a separation L₃ of 70 nm.

In the simulation of FIG. 6, the value of the capacitance (“CAP-LINE capacitance”) formed between the model capacitor 10A and the wiring pattern 13C is obtained for each of the cases of setting the distance b between the wiring pattern 13C and the electrode pattern 13B to specific values of 420 nm, 800 nm and 1.5 μm, by changing the extension distance a from 0.05 μm to 1.43 μm by changing the length of the electrode pattern 13A. In FIG. 6, the horizontal axis represents the distance a while the vertical axis represents the “CAP-LINE capacitance”.

In the model capacitor 10A of FIG. 7, the electrode patterns 13A are connected to the ground pattern 13G at the respective ends away from the wiring pattern 13C, wherein it should be noted that a distance L₄ between the ground pattern 13G and the end of the electrode pattern 13B opposing the ground pattern 13G is set also to 70 nm.

Referring to FIG. 6, in any of the cases in which the distance b is set to the foregoing values, it can be seen that the value of the capacitance “CAP-LINE capacitance” decreases with the value of the distance a, and thus, the electrostatic shielding effect of the electrode patterns 13B by the electrode patterns 13A explained with reference to FIG. 3A is confirmed. Further, it can be seen that the larger the distance b, the larger the decrease of the capacitance “CAP-LINE capacitance” attained by the increase of the distance a. This indicates that the shielding effect appears more conspicuously by causing the electrode pattern 13A to extend with respect to the electrode pattern 13B.

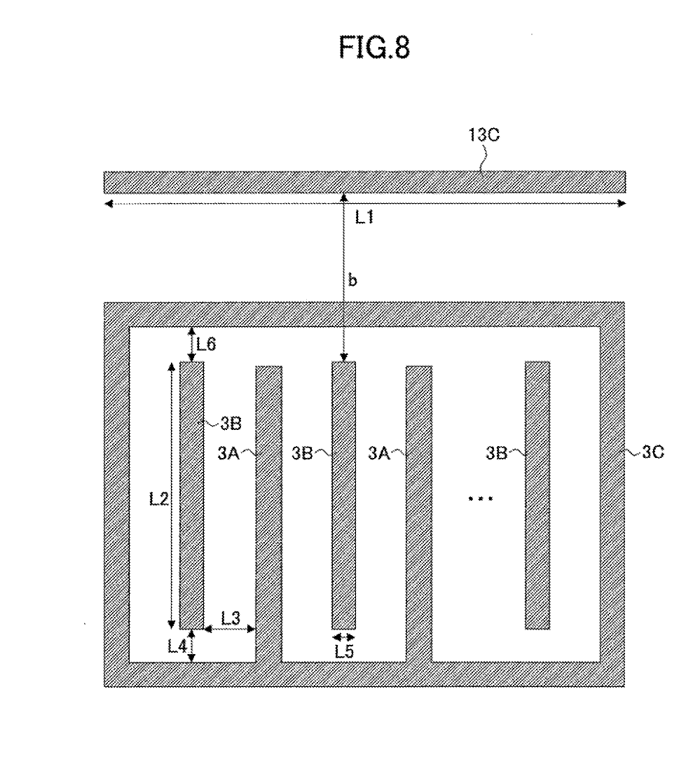

FIG. 8 represents the model structure for the case a similar simulation is carried out for the MIM capacitor 100 according to the comparative example of FIG. 4.

Referring to FIG. 8, the array of linear electrode patterns 3A and 3B is surrounded by the ground pattern 3C in the model structure, wherein the electrode patterns 3A and 3B are formed such that the respective ends thereof are separated from the ground pattern 3C by a distance L₆, which is set to 70 nm. Further, the other ends of the electrode patterns 3A are connected to the ground pattern 3C. The distances L₁-L₅ are set similarly to the case of the model structure of FIG. 7.

In the model structure of FIG. 8, it can be seen that a capacitance of 1.11×10⁻¹⁶ F is obtained for the value of the capacitance “CAP-LINE capacitance” indicating the effect of the ground pattern 3C as represented by the open square in FIG. 6 when the distance b is set to 420 nm, while in the case the distance b is set to 800 nm, a capacitance of 7.86×10⁻¹⁷ F is obtained for the value of the capacitance “CAP-LINE capacitance” indicating the effect of the ground pattern 3C as represented by the open triangle in FIG. 6, and in the case the distance b is set to 1.5 μm, a capacitance of 4.85×10⁻¹⁷ F is obtained for the value of the capacitance “CAP-LINE capacitance” indicating the effect of the ground pattern 3C as represented by the open diamond in FIG. 6.

Thus, when to attain the electrostatic shielding effect similar to that attained by the ground pattern 3C of the capacitor 100 of the comparative example of FIG. 4, with the MIM capacitor 10 of the present embodiment, it can be seen that the distance a may be set about three times or more, preferably about 3.6 times or more of the separation L, and thus, the distance a may be set to about 210 nm or more, preferably about 250 nm in the case the distance L is 70 nm.

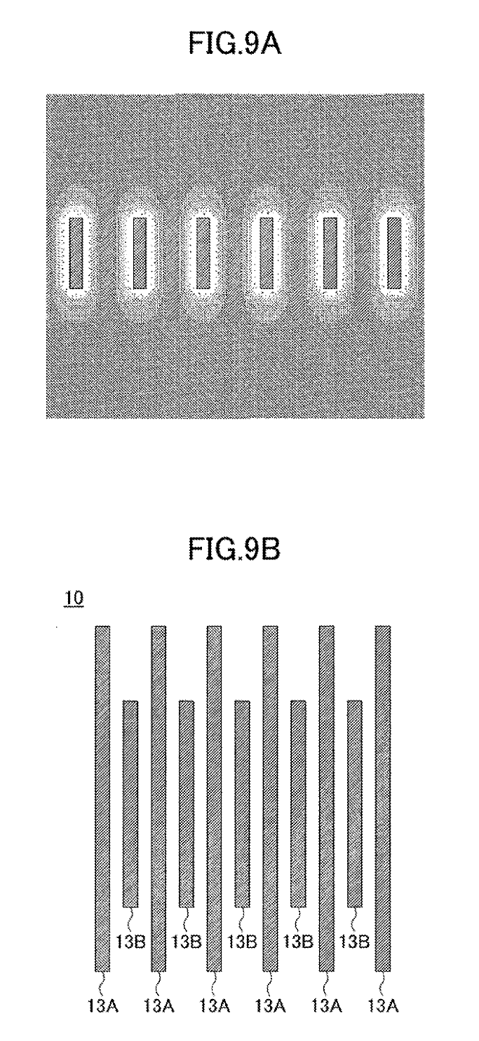

FIG. 9A is a diagram depicting the electric field distribution obtained with the foregoing simulation for the MIM capacitor 10 of the present embodiment shown in FIG. 9B in the form of a two-dimensional map. It can be seen that there is caused no leakage of the electric field around the electrode pattern 13B beyond the tip end of the electrode patterns 13A.

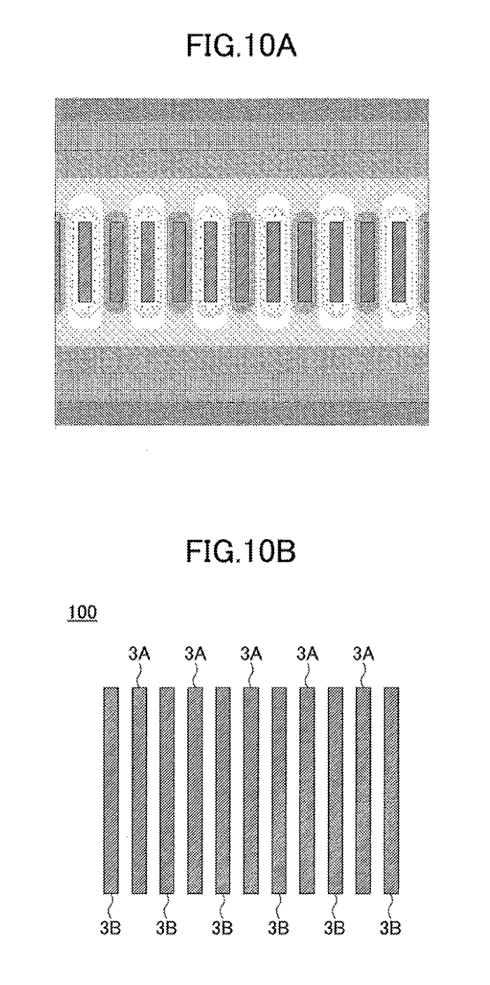

In contrast, FIG. 10A represents the results of the two-dimensional mapping of the similar electric field distribution for the electrode array of the MIM capacitor 100 of FIG. 3B shown in FIG. 10B.

Referring to FIG. 10A, it can be seen that the electric field leaks out beyond the tip ends of the electrode patterns 3A and 3B with the electrode array of FIG. 10B, and thus, it will be understood that shielding by the ground electrode 3C is indispensable in the electrode array of FIG. 10B.

Thus, with the MIM capacitor 10 according to the present embodiment, the first end 13A₁ of the first electrode pattern 13A extends beyond the first end 13B₁ of the second electrode pattern 13B corresponding to the foregoing first end 13A₁ and the second end 13A₂ of the first electrode pattern 13A opposite to the foregoing first end 13A₁ extends beyond the second end 13B₂ of the second electrode pattern 13B, which corresponds to the second end 13A₂, and thus, the second electrode patterns 13B are effectively shielded electrostatically by grounding the first electrode patterns 13A. There is no longer the need of providing a separate shielding pattern. Because the first and second electrode patterns 13A and 13B are supplied with the first and second voltages via the respective via-plugs 14Va and 14Vb, there is no longer the need of forming a wiring pattern on the same plane in close proximity of the end 13A₁ or 13A₂ or the end 13B₁ or 13B₂. Thus, it becomes possible to form the first electrode patterns 13A of linear shape and the second electrode patterns 13B of linear shape with high precision with regard to the size while avoiding deformations caused by optical proximity effect, and the like. Thus, it becomes possible to realize high precision capacitance.

In the present embodiment, it should be noted that the width and the separation of the electrode patterns 13A and 13B are by no means limited to the foregoing value of 70 nm but may be in the range of 10 nm-200 nm. Further, the length of the electrode patterns 13A and 13B is not limited to 2.5 μm but may be in the range of 1 μm-100 μm.

### Second Embodiment

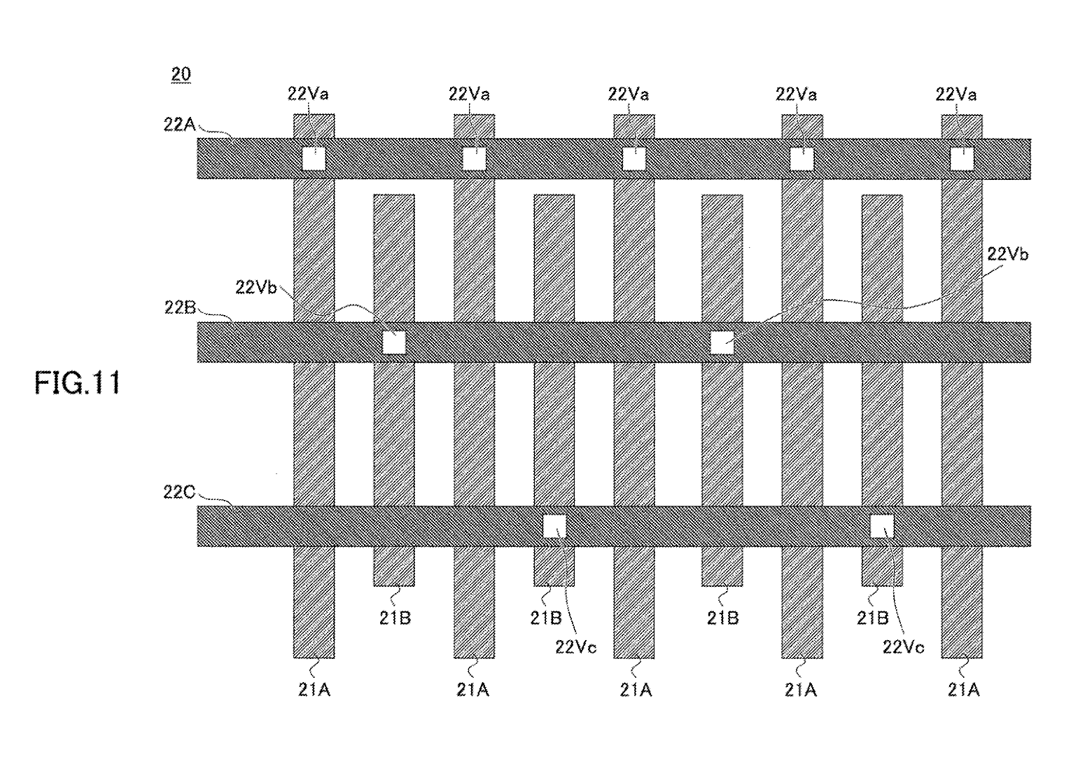

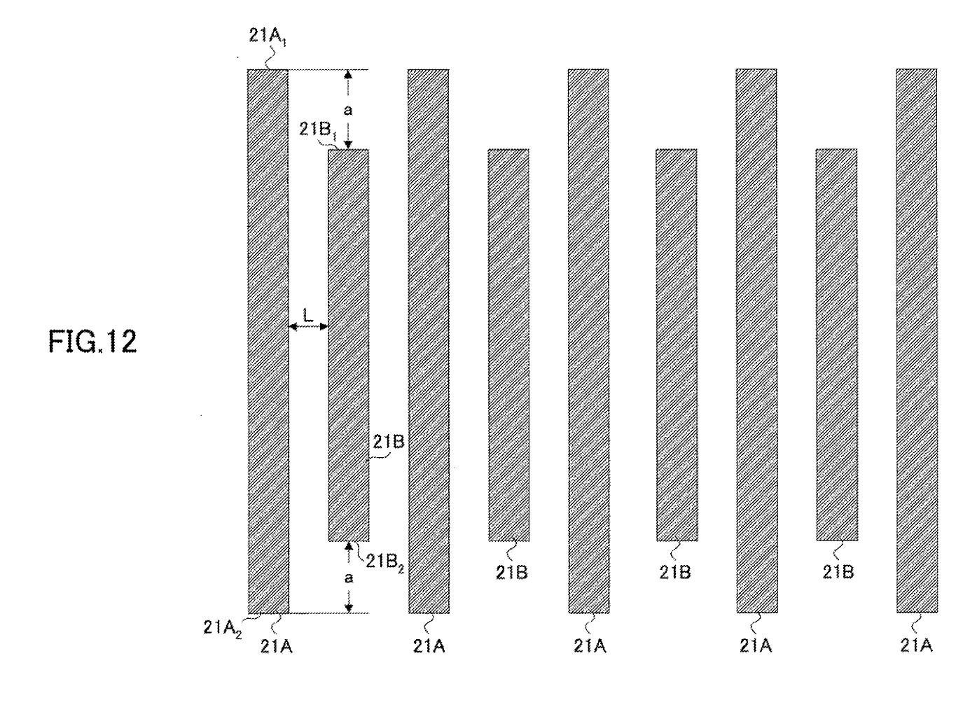

FIG. 11 is a plan view diagram representing an MIM capacitor 20 according to a second embodiment. Further, FIG. 12 is a plan view diagram representing the array of the electrode patterns of the MIM capacitor. Because the MIM capacitor 20 has a cross-section similar to that of the MIM capacitor 10, and thus, explanation thereof will be omitted.

Referring to FIG. 11, there are formed electrode patterns 21A and 21B respectively corresponding to the electrode patterns 13A and 13B in the MIM capacitor 20 such that the electrode patterns 21A and 21B are formed repeatedly on a plane, wherein a wiring pattern 22A corresponding to the wiring pattern 14A is connected to each of the electrode patterns 21A by respective via-plugs 22Va. Further, with the present embodiment, a wiring pattern 22B corresponding to the wiring pattern 14B is connected electrically to the electrode patterns 21B alternately and thus skipping an electrode pattern 21B in every two electrode patterns 21B, by way of via-plugs 22Vb.

Further, with the present embodiment, another wiring pattern 22C is connected, by via-plugs 21Vc, to the electrode patterns 21B alternately and hence to those electrode patterns 21B not connected to the wiring pattern 22B.

Referring to FIG. 12, it can be seen that a tip end 21A₁ of the electrode pattern 21A extends beyond a corresponding tip end 21B₁ of the electrode pattern 21B by a distance a, and a tip end 21A2 at an opposite side of the tip end 21A₁ extends beyond a tip end 21B₂, which is at the opposite end of the tip end 21B₁ similarly to the plan view of FIG. 2. Thus, in the case the electrode patterns 13A and 13B have the width of 70 nm and are repeated with a separation L, it becomes possible to suppress the leakage of the electric field from the MIM capacitor 20 without surrounding the MIM capacitor 20 with the ground pattern such as the pattern 3C in FIG. 4, by setting the distance a to be about three times of more, preferably abut 3.6 times or more, of the separation L.

According to the present embodiment, it becomes possible to form a first capacitor by the electrode patterns 21A and 21B and a second capacitor by the electrode patterns 21A and 21C in the same MIM capacitor 20, with high precision. Thus, the MIM capacitor is suitable for the applications in which the relative precision of the two capacitors is important. Further, with the MIM capacitor 20 of the present embodiment, it should be noted that the electrode pattern 21B connected with wiring pattern 22B and the electrode pattern 21B connected to the wiring pattern 22C are separated from each other eclectically by the intervening electrode pattern 21A, and thus, it becomes possible to suppress the cross-talk of the signals supplied through the wiring pattern 22B and the signals supplied through the wiring patterns 22C.

Further, in the present embodiment, it is also possible to form an arbitrary number of capacitors, such as a third capacitor, fourth capacitor, and the like, in the same MIM capacitor 20.

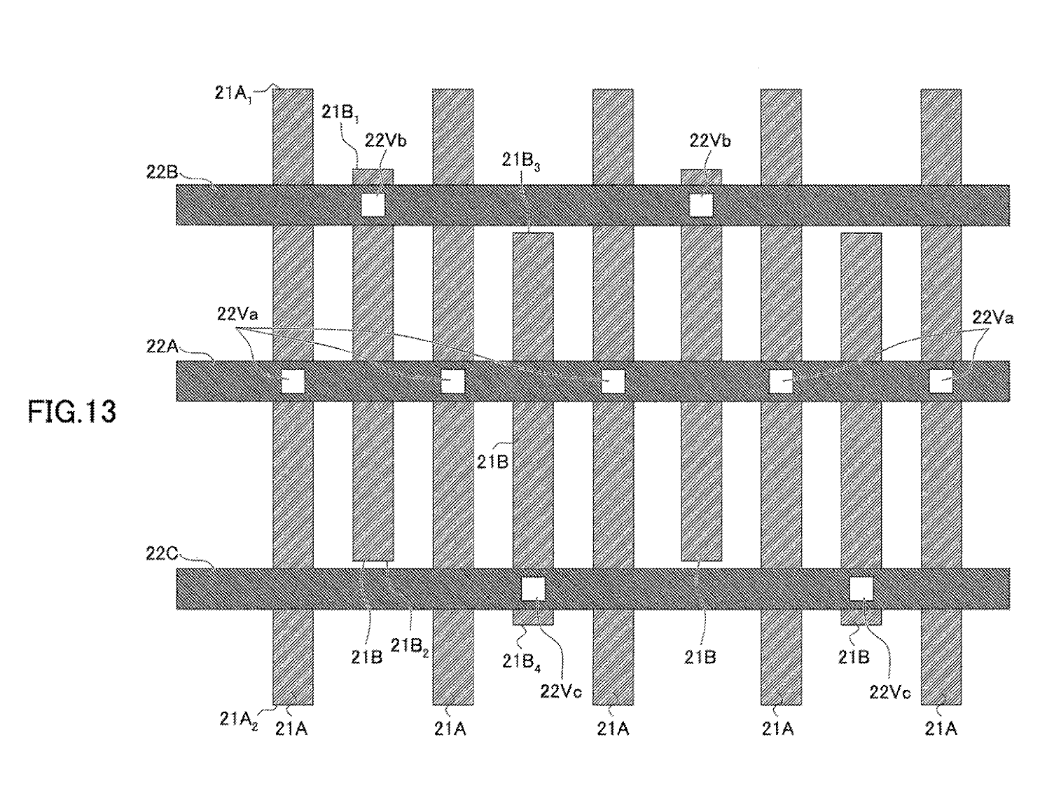

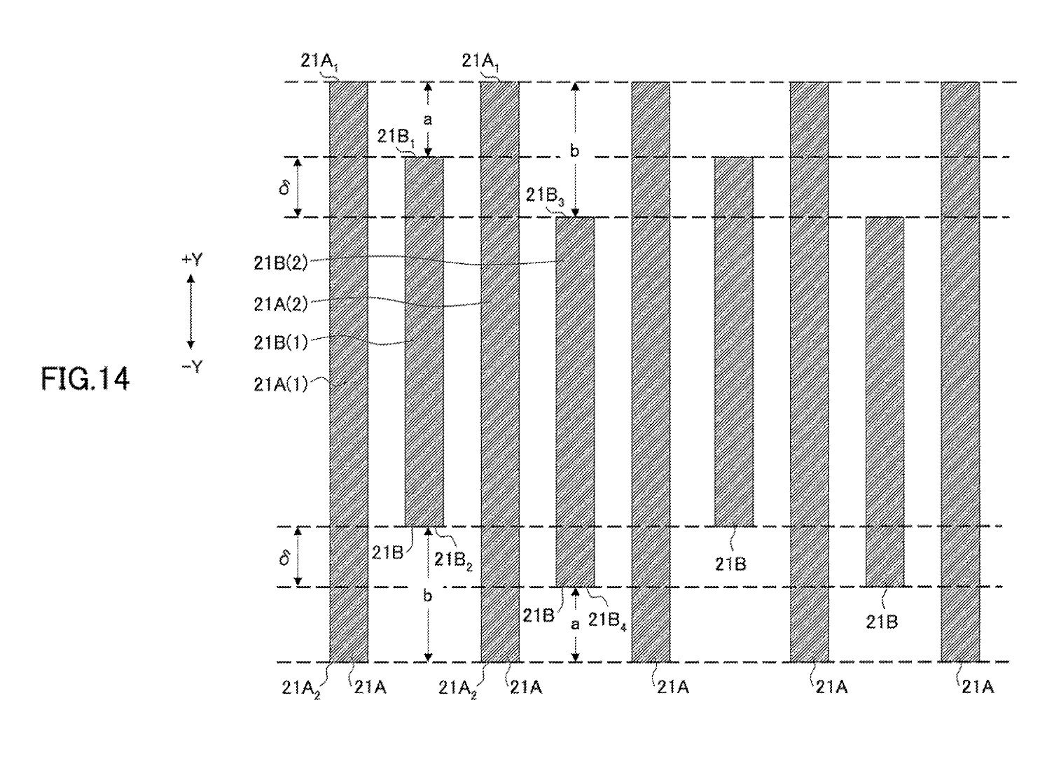

FIG. 13 is a plan view diagram representing the construction of an MIM capacitor 20A according to a modification of the present embodiment and FIG. 14 is a plan view diagram representing the array of the electrode patterns in the MIM capacitor 20A of FIG. 13. In the drawings, those parts explained before are designated by the same reference numerals and the description thereof will not be repeated.

Referring to FIGS. 13 and 14, the electrode patterns 21B₁ of the MIM capacitor 20 are displaced, in the present embodiment, in the elongating direction of the electrode patterns 21A alternately by a distance δ, and thus, it becomes possible to realize the layout that the wiring pattern 22A is contacted to the electrode patterns 21A by the via-plugs 22Va at the central part thereof along the elongating direction, the wiring pattern 22B is contacted to the electrode patterns 21B by the via-plugs 22Vb in the vicinity of the tip end 21B₁ corresponding to the tip end 21A₁ and the wiring pattern 22C is connected to another of the electrode patterns 21B by the via-plugs 22Vc in the vicinity of the tip end 21B₄ corresponding to the tip end 21A₂ opposite to the electrode pattern 21B. With such a layout, it becomes possible to form the wiring patterns 22A-22C with uniform interval and the problem of specific patterns come close to each other at the time of the layout. Further, it becomes possible to reduce the overall area of the MIM capacitor.

In FIG. 14, it should be noted that, for the convenience of the explanation, the electrode patterns 21A are provided with the labels 21A(1), 21A(2), . . . consecutively from the left side to the right side and the electrode patterns 21B are provided with the labels 21B(1), 21B(2), . . . consecutively from the left side to the right side.

As can be seen from FIG. 14, the tip end 21A₁ of the leftmost electrode pattern 21A(1) of the drawing extends by a distance a as compared with the tip end 21B₁ of the adjacent electrode pattern 21B(1) in the +Y direction of the elongating direction of the electrode pattern 21A(1). Further, it can be seen that the tip end 21A₂ of the electrode pattern 21A(2) adjacent to the electrode pattern 21B(1) at the right side thereof extends by the distance a with respect to the corresponding tip end 21B₄ of the electrode pattern 21B(2), which is adjacent to the electrode pattern 21(2) at the right side thereof, in the −Y direction of the elongating direction of the electrode pattern 21A(2).

Comparing with the end 21B₂ of the electrode pattern 21B(1), because the electrode patterns 21B(1) and 21B(2) have the same length, the tip end 21A₂ at the opposite side of the tip end 21A₁ of the electrode pattern 21A(1) extends by a distance b larger than the distance a by δ, with respect to the corresponding tip end 21B₂ of the electrode pattern 21B(2) in the −Y direction, along the elongating direction of the electrode pattern 21A(1) (b=a+δ). Similarly, the tip end 21A₁ of the electrode pattern 21A(2) extends beyond the tip end of the electrode pattern 21B(2) in the +Y direction of the elongating direction of the electrode pattern 21A(2) with the distance b as compared with the tip end of the electrode pattern 21(B).

### Third Embodiment

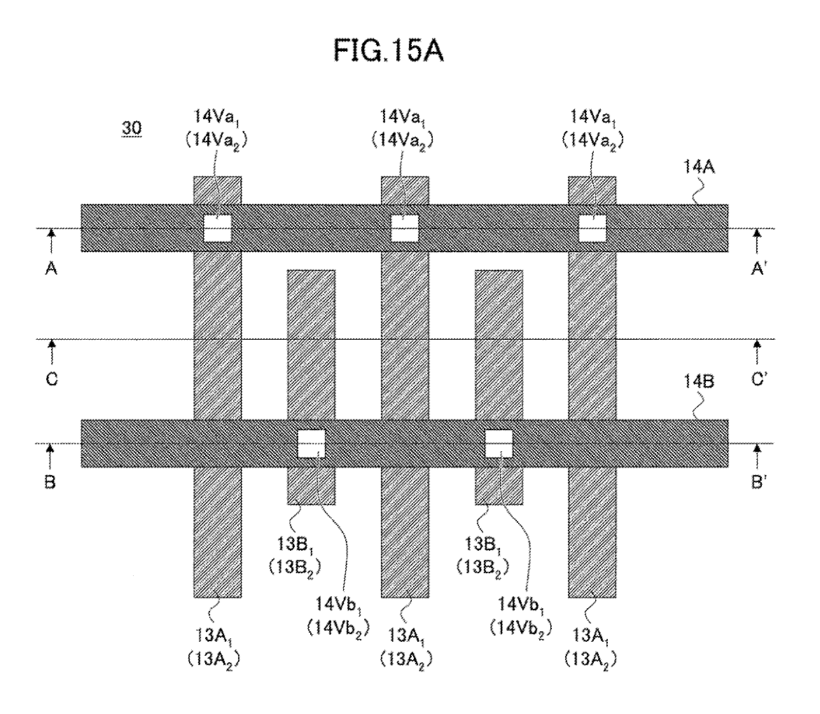

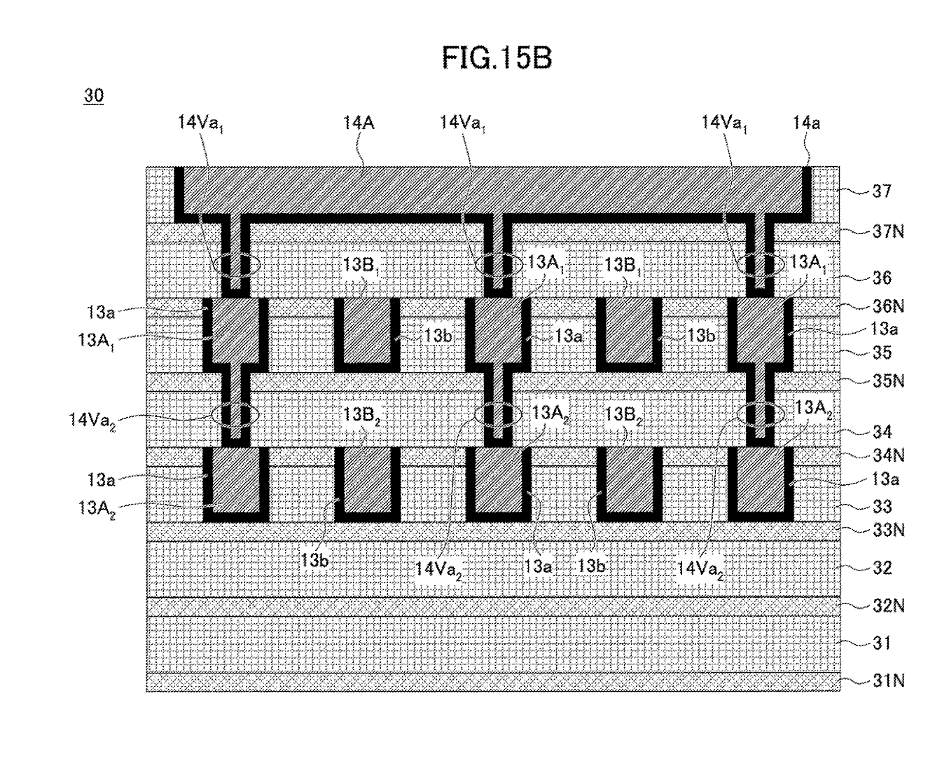

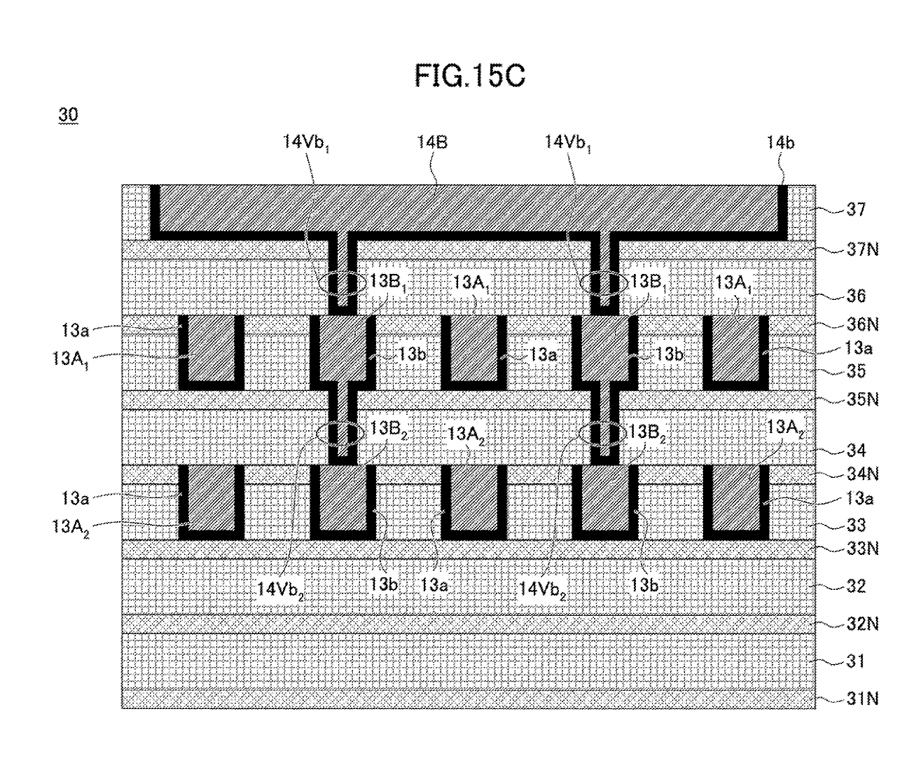

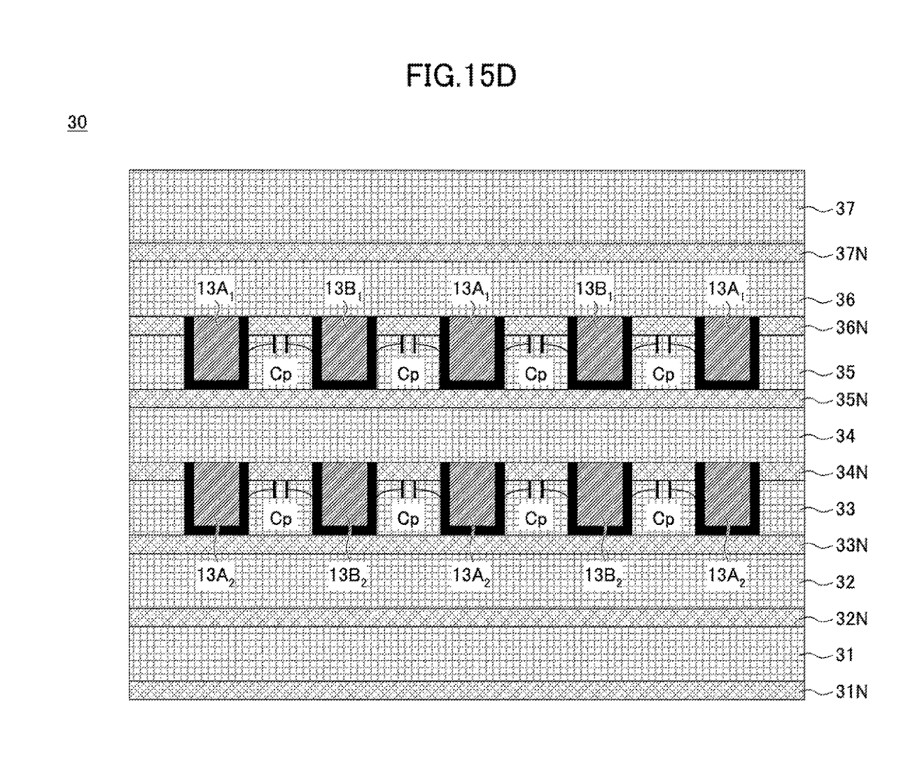

FIGS. 15A-15D represent the construction of an MIM capacitor 30 according to a third embodiment. Here, it should be noted that FIG. 15A is a plan view diagram representing the MIM capacitor 30, FIG. 15B is a cross-sectional diagram of the MIM capacitor 30 taken along a line A-A′ of FIG. 15A, FIG. 15C is a cross-sectional diagram taken along a line B-B′ of FIG. 15A, and FIG. 15D is a cross-sectional diagram taken along a line C-C′ of FIG. 15A. In the drawings, those parts explained before are designated by the same reference numerals and the description thereof will be omitted.

Referring to FIG. 15A, the MIM capacitor has a plan view similar to that of the MIM capacitor 10 of FIG. 1A, except that, as depicted in the cross-sectional diagram of FIG. 15B or FIG. 15C, there are formed a plurality of electrode patterns 13A₁ and 13A₂ corresponding to the electrode patterns 13A of FIG. 1A in the form of array to form respective wiring layers, one located above the other, and there are further formed a plurality of electrode patterns 13B₁ and 13B₂ also in the form of array in the respective wiring layers one located above the other, such that the wiring layer of the electrode patterns 13B₁ corresponds to the wiring layer of the electrode patterns 13A₁ and the wiring layer of the electrode patterns 13B₂ corresponds to the wiring layer of the electrode patterns 13A₂. As shown in the cross-sectional diagram of FIG. 15B and FIG. 15C, the wiring patterns 14A and 14B are formed in the wiring layer above the wiring layer of the electrode patterns 13A₁ and 13A₂, wherein the wiring pattern 14A is connected to the respective electrode patterns 13A₁ by via-plugs 14Va₁ corresponding to the via-plugs 14Va electrically, while the wiring pattern 14B is connected to the respective electrode patterns 13B₁ electrically by via-plugs 14Vb₁, which correspond to the via-plugs 14Vb.

Referring to the cross-sectional diagram of FIG. 15B, the MIM capacitor 30 is formed in a stacked structure in which there are stacked an etching stopper film 31N such as an SiN film or SiC film and an interlayer insulation film 31 of a silicon oxide film or a so-called Low-K film, and there are further stacked consecutively a similar etching stopper film 32N, a similar interlayer insulation film 32, a similar etching stopper film 33N, an interlayer insulation film 33, an etching stopper film 34N, an interlayer insulation film 34, an etching stopper film 35N, an interlayer insulation film 35, an etching stopper film 36N, an interlayer insulation film 36,k an etching stopper film 37N, and an interlayer insulation film 37, wherein the electrode patterns 13A₁ and 13B₁ are formed in the trenches in the interlayer insulation film 33 alternately by a damascene process while using the etching stopper film 33N as an etching stopper.

Similarly, the electrode patterns 13A₁ and 13B₁ are formed in the trenches formed in the interlayer insulation film by a damascene process while using the etching stopper film 35N as an etching stopper. Each of the electrode patterns 13A₁ is connected to the electrode pattern 13A₂ right underneath electrically by a via-plug 14Va₂ formed by a dual damascene process as represented in FIG. 15B, and each of the electrode patterns 13B₁ is connected electrically to the electrode pattern 13B₂ right underneath by a via-plug 14Vb₂ formed by a dual damascene process as represented in FIG. 15B.

Further, in the trenches formed in the interlayer insulation film 37, there are formed the wiring patterns 14A and 14B by a damascene process as represented in FIGS. 15B and 15C, wherein the wiring pattern 14A is connected electrically to the electrode pattern 13A₁ by a via-plug 14Va₁ formed by a dual damascene process. Similarly, the wiring pattern 14A is connected to the electrode patterns 13A₁ electrically by the via-plugs 14Va1 formed by the dual damascene process. Similarly, the wiring pattern 14A is connected to the electrode patterns 13B₁ electrically by the via-plugs 14Vb₁ formed by the dual damascene process as represented in FIG. 15C.

In the present embodiment, each of the electrode patterns 13A₁ and 13A₂, the electrode patterns 13B₁ and 13B₂, and the wiring patterns 14A and 14B is typically formed of a copper pattern and accompanied with the barrier metal film 13a, 13b, 14a or 14b of the Ti/TiN stacked structure or the Ta/TaN stacked structure.

With the MIM capacitor 30 of such a construction, it is possible to supply the ground voltage to the electrode patterns 13A₁ and 13A₂ and a signal voltage to the electrode patterns 13B₁ and 13B₂, by supplying the ground voltage to the wiring pattern 14A and the signal voltage to the wiring pattern 14B.

FIG. 15D is a diagram schematically representing the occurrence of the capacitance for the case the ground voltage is supplied to the wiring pattern 14A and a predetermined signal voltage is supplied to the wiring pattern 14B along a cross-section C-C′ in the plan view of FIG. 15A.

Referring to FIG. 15D, there are formed a capacitance Cp between the electrode patterns 13A₁ and 13B₁ and between the electrode patterns 13A₂ and 13B₂. Thus, with the present embodiment, it becomes possible to increase the capacitance of the MIM capacitor 30 by increasing the number of the electrode patterns. Further, according to the present embodiment, it should be noted that the electrode patterns 13A₁ and 13B₁ and the electrode patterns 13A₂ and 13B₂ are the patterns of linear shape, and there exists no such a pattern that is exposed in the close proximity at the time of photolithography. Thus, it is possible to attain high precision patterning and the MIM capacitor 30 can provide high precision capacitance.

### Fourth Embodiment

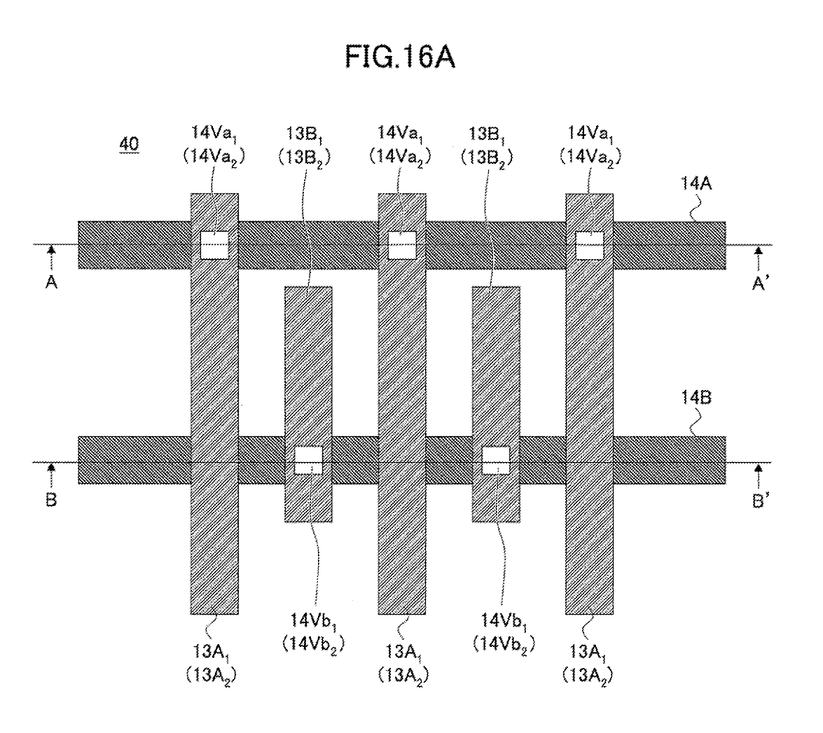

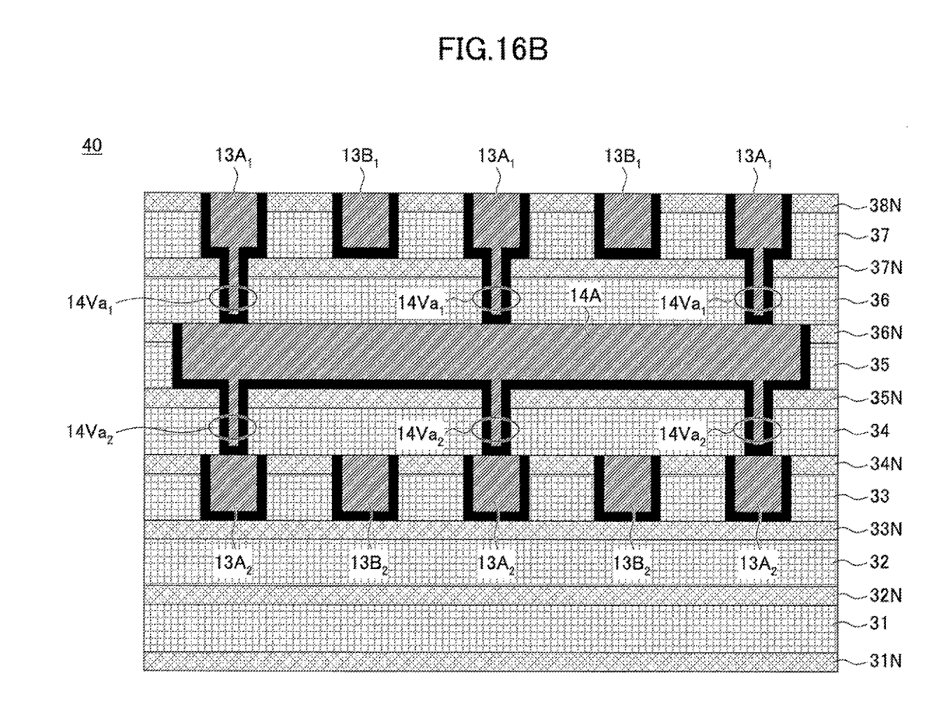

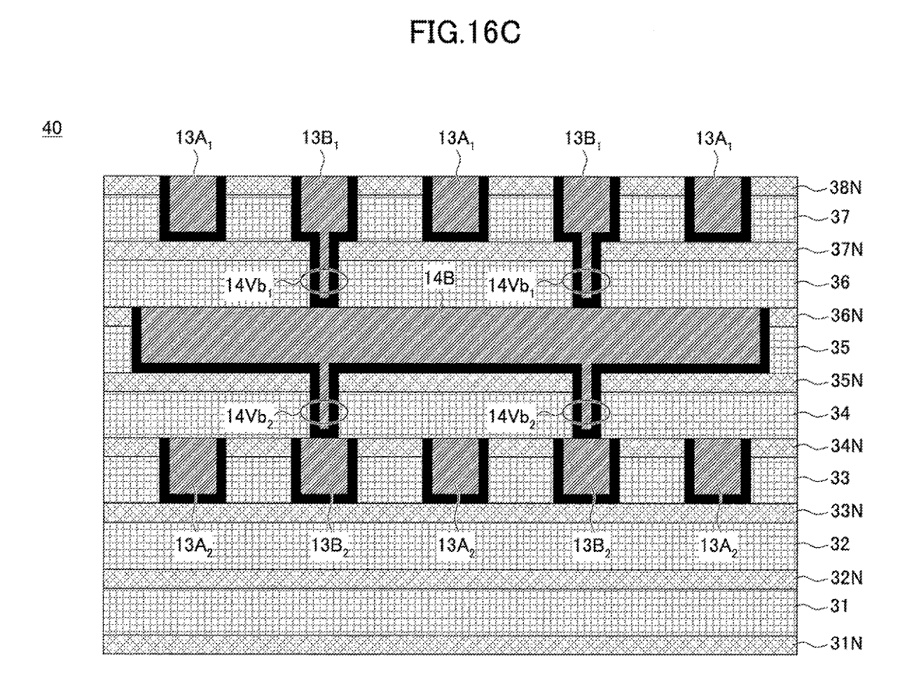

FIGS. 16A-16D show the construction of an MIM capacitor 40 according to a fourth embodiment. Here, FIG. 16A is a plan view diagram depicting the MIM capacitor 40 while FIG. 16B is a cross-sectional view of the MIM capacitor 40 along a line A-A′ of FIG. 16A and FIG. 16C is a cross-sectional diagram of the MIM capacitor 40 according to a line B-B′. In the drawings, those parts explained before are designated by the same reference numerals and the description thereof will be omitted.

Referring to FIG. 16A, the MIM capacitor has a plan view similar to that of the MIM capacitor 10 of FIG. 1A, except that, as depicted in the cross-sectional diagrams of FIG. 16B and FIG. 16C, there are formed arrays of electrode patterns 13A₁ and 13A₂ corresponding to the electrode patterns 13A of FIG. 1A one above the other, and there are also formed arrays of electrode patterns 13B₁ and 13B₂ corresponding to the electrode pattern 13B of FIG. 1A one above the other. As represented in the cross-sectional diagram of FIGS. 15B and 15C, the electrode patterns 13A₁ and 13B₁ are formed in the uppermost wiring layer while the electrode patterns 13A₂ and 13B₂ are formed in the lowermost wiring layer, and the wiring pattern 14A is formed in the intermediate wiring layer. The wiring pattern 14A is connected to the respective electrode patterns 13A₁ electrically by the via-plugs 14Va₁ corresponding to the via-plug 14Va in the plan view of FIG. 1A, and the wiring pattern 14B is connected electrically to the respective electrode patterns 13B₁ by the via-plugs 14Vb₁ corresponding to the via-plug 14Vb in the plan view of FIG. 1A.

Referring to the cross-sectional diagrams of FIGS. 16B and 16C, it can be seen that, in the present embodiment, too, the MIM capacitor 40 is formed in the stacking structure in which the etching stopper layer 31N, the interlayer insulation film 31, the etching stopper film 32N, the interlayer insulation film 32, the etching stopper film 33N, the interlayer insulation film 33, the etching stopper film 34N, the interlayer insulation film 34, the etching stopper film 35N, the interlayer insulation film 35, the etching stopper film 36N, the interlayer insulation film 36, the etching stopper film 37N, the interlayer insulation film 37 and the etching stopper film 38N are stacked consecutively, wherein it should be noted that the wiring patterns 14A and 14B are formed in the interlayer insulation film 35, the electrode patterns 13A₁ and 13B₁ are formed in the upper interlayer insulation film 27 above the interlayer insulation film 35, and the electrode patterns 13A₂ and 13B₂ are formed in the lower interlayer insulation film 33 below the interlayer insulation film 35. Thereby, the electrode patterns 13A₁ are connected to the top surface of the wiring pattern 14A by the via-plug 14Va₁ formed by dual damascene process and extends downward from the electrode pattern 13A₁, while electrode patterns 13B₁ are connected to the top surface of the wiring pattern 14B by the via-plug 14Vb₁ formed by dual damascene process and extends downward from the electrode pattern 13B₁. Further, the electrode patterns 13A₂ are connected to the wiring pattern 14A by the via-plugs 14Va₂ formed by dual damascene process and extends downward from the wiring pattern 14A, while the electrode patterns 13B₂ are connected to the wiring pattern 14B by the via-plugs 14Vb₂ formed by dual damascene process and extends downward from the wiring pattern 14B.

With such a structure, it is possible to increase the capacitance of the MIM capacitor 40 similarly to the MIM capacitor 10 of the previous embodiment by increasing the number of the electrode patterns. Further, with the present embodiment, too, the electrode patterns 13A₁, 13B₁, 13A₂ and 13B₂ are formed of parallel and linear patterns, and thus, there is formed no other conductive pattern in close proximity of the tip end thereof in the same plane. Thus, it is possible to form the patterns by photolithography with high precision, and it becomes possible to realize high capacitance.

Further, by comparing the previous embodiment of FIGS. 15A-15D, in which it has been necessary to conduct voltage supply to the electrode patterns 13B₂ consecutively by two via-plugs 14Vb₁ and 14Vb₂, while in the present embodiment, it is possible to conduct voltage supply to any of the electrode patterns 13B₁ and 13B₂ by a single via-plug 14Vb₁ or 14Vb₂, and thus, it is possible to reduce the parasitic resistance and CR product with the MIM capacitor 40.

### Fifth Embodiment

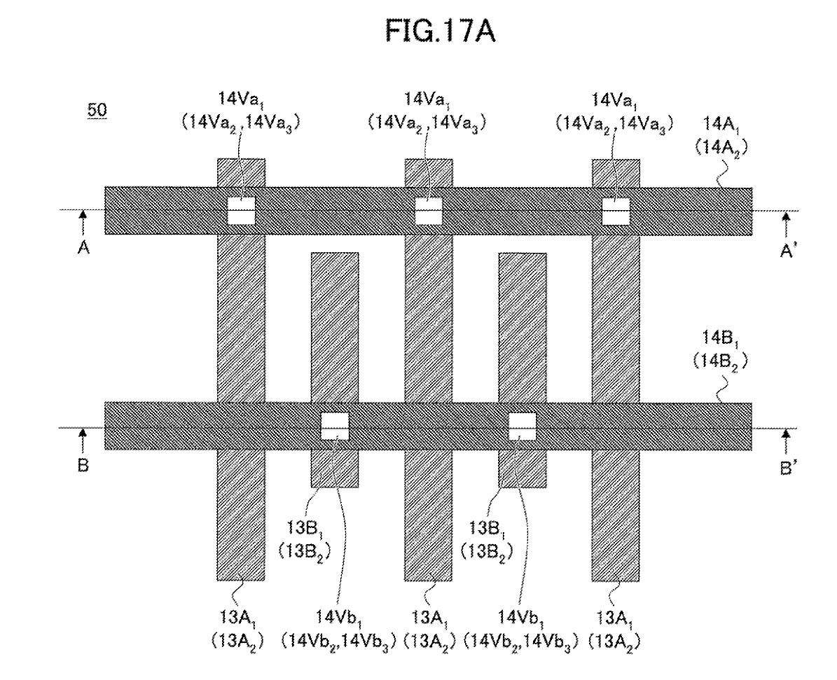

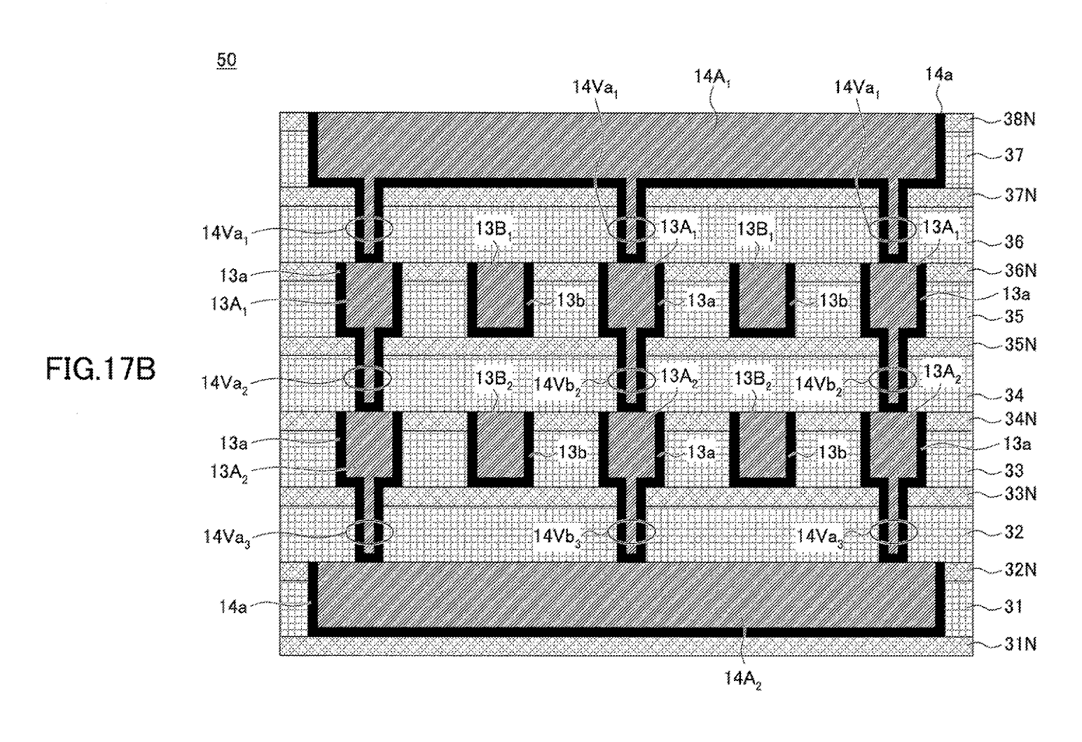

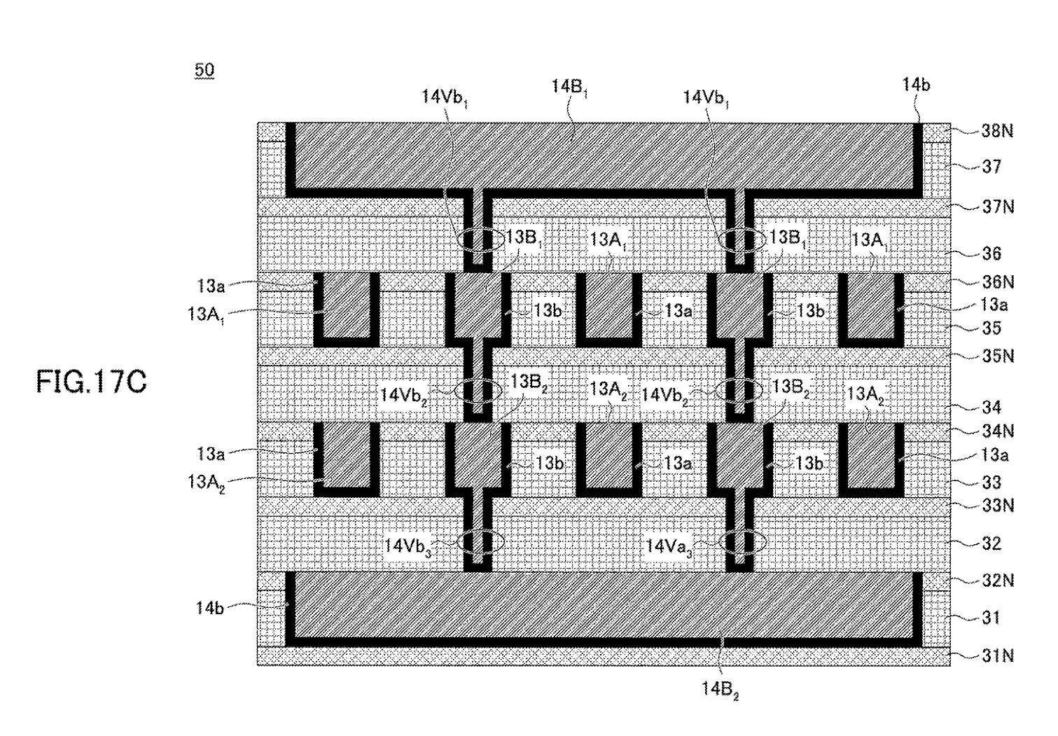

FIGS. 17A-17D represent the construction of an MIM capacitor 50 according to a fifth embodiment. Here, FIG. 17A is a plan view diagram depicting the MIM capacitor 50 while FIG. 17B is a cross-sectional view of the MIM capacitor 50 along a line A-A′ of FIG. 17A and FIG. 17C is a cross-sectional diagram of the MIM capacitor 50 according to a line B-B′. In the drawings, those parts explained before are designated by the same reference numerals and the description thereof will be omitted.

Referring to FIG. 17A, the MIM capacitor 50 has a plan view similar to the plan view of the MIM capacitor 10 of FIG. 1A, except that, as depicted in the cross-sectional diagrams of FIG. 17B and FIG. 17C, there are formed arrays of electrode patterns 13A₁ and 13A₂ corresponding to the electrode patterns 13A of FIG. 1A one above the other, and there are also formed arrays of electrode patterns 13B₁ and 13B₂ corresponding to the electrode pattern 13B of FIG. 1A one above the other.

As represented in the cross-sectional diagram of FIG. 17B, the MIM capacitor 50 is formed in a stacked structure in which the etching stopper film 31N, the interlayer insulation film 31, the etching stopper film 32N, the interlayer insulation film 32, the etching stopper film 33N, the interlayer insulation film 33, the etching stopper film 34N, the interlayer insulation film 34, the etching stopper film 35N, the interlayer insulation film 35, the etching stopper film 36N, the interlayer insulation film 36, the etching stopper film 37N, the interlayer insulation film 37 and the etching stopper film 37 are stacked consecutively, wherein, in the present embodiment, the wiring pattern 14A₁ is formed in the uppermost interlayer insulation film 37 in correspondence to the wiring pattern 14A of FIG. 1A and the via plugs 14Va₁ formed by dual damascene process and extending downward from the wiring pattern 14A₁ make a contact to the top surface of the electrode patterns 13A₁. Further, with the present embodiment, there is formed a wiring pattern 14A₂ corresponding to the wiring pattern 14A in the lowermost interlayer insulation film 31, and via-plugs 14Va₃, formed by dual damascene process and extending downward from the electrode patterns 13A₂, make a contact with the top surface of the wiring patterns 13A₂. Further, via-plugs 14Va₂ formed by dual damascene process extend also from the electrode patterns 13A₁ in the downward direction and make contact with the top surface of the electrode patterns 13A₂.

Further, as depicted in the cross-sectional diagram of FIG. 17C, the wiring pattern 14B₁ corresponding to the wiring pattern 14B of FIG. 1A is formed in the uppermost interlayer insulation film 37, and the via-plugs 14Vb₁, formed by dual damascene process, extends from the wiring pattern 14B1 in the downward direction and make a contact with the top surface of the electrode patterns 13B₁. Further, with the present embodiment, there is formed a wiring pattern 14B₂ corresponding to the wiring pattern 14B in the lowermost interlayer insulation film 31, and via-plugs 14Vb₃, formed by dual damascene process and extending downward from the electrode patterns 13B₂, make a contact with the top surface of the wiring patterns 14B₂. Further, via-plugs 14Vb₂ formed by dual damascene process extend also from the electrode patterns 13B₁ in the downward direction and make contact with the top surface of the electrode patterns 13B₂.

In the present embodiment, the wiring patterns 14A₁, 14A₂, 14B₁ and 14B₂ are formed of copper, for example, and the wiring patterns 14A₁, 14A₂, 14B₁ and 14B₂ are formed by a damascene process or dual damascene process so as to fill a trench formed in the interlayer insulation film 37 or 31 via a barrier metal film 14a or 14b of the Ti/TiN structure or Ta/TaN structure. Similarly, the electrode patterns 13A₁ and 13B₁ are formed of copper, for example, and the electrode patterns 13A₁ and 13B₁ are formed by a damascene process or dual damascene process so as to fill the trenches formed in the interlayer insulation film 35 via the barrier metal film 13a or 13b of the Ti/TiN structure or Ta/TaN structure. Further, the electrode patterns 13A₁ and 13B₁ are formed of copper, for example, and the electrode patterns 13A₁ and 13A₂ are formed by a damascene process or dual damascene process so as to fill the trenches formed in the interlayer insulation film 33 via the barrier metal film 13a or 13b of the Ti/TiN structure or Ta/TaN structure.

With such a structure, it is possible to increase the capacitance of the MIM capacitor 50 similarly to the MIM capacitor 10 of the previous embodiment by increasing the number of the electrode patterns. Further, with the present embodiment, too, the electrode patterns 13A₁, 13B₂, 13A₂ and 13B₂ are formed of parallel and linear patterns, and thus, there is formed no other conductive pattern in close proximity of the tip end thereof in the same plane. Thus, it is possible to form the patterns by photolithography with high precision, and it becomes possible to realize high capacitance.

Further, comparing with the embodiment of FIGS. 15A-15D, it is possible, with the MIM capacitor 50 of the present embodiment, to supply the voltages to the electrode patterns 13A₁ and 13A₂ in the upper and lower wiring layers from the two wiring layers 14A₁ and 14A₂ respectively formed in the further upper and further lower wiring layers, via the respective via-plugs 14Va₁ and 14Va₃. Further, it is possible to supply the voltages to the electrode patterns 13B₂ and 13B₂ respectively in the upper and lower wiring layers from the two wiring patterns 14B₁ and 14B₂ respectively formed in the further upper and further lower wiring layers via the respective via-plugs 14Vb₁ and 14Vb₃. As a result, it is possible with the present embodiment to reduce the parasitic resistance and the CR product. Further, the electrode patterns 13A₁ are connected electrically to the electrode patterns 13A₂ right underneath respectively by the via-plugs 14Va₂, and the electrode patterns 13B₁ are connected electrically to the electrode patterns 13B₂ right underneath respectively by the via-plugs 14Vb₂, and thus, there occurs no such formation of parasitic capacitance with the upper layer or with the lower layer, and it becomes possible to provide high precision capacitance.

### Sixth Embodiment

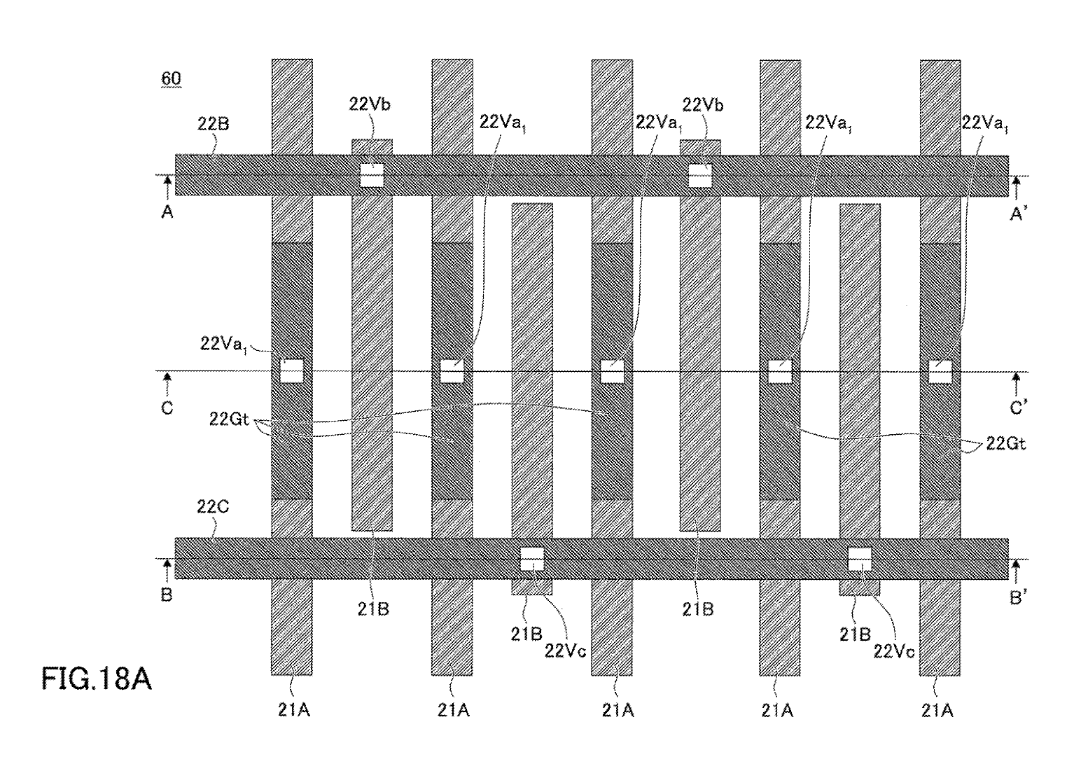

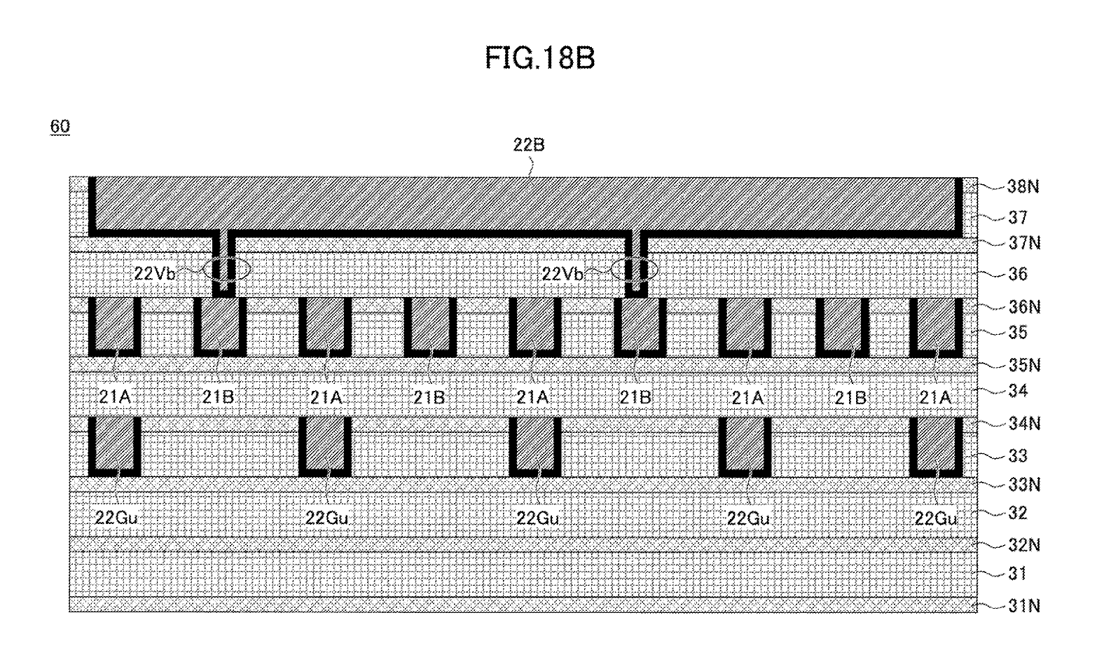

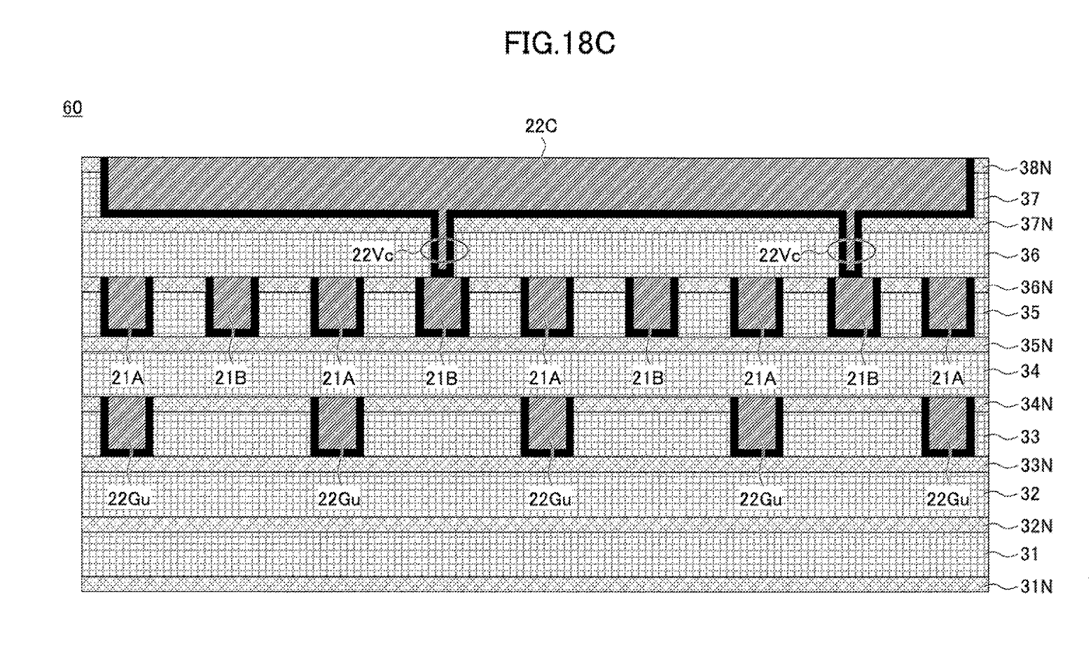

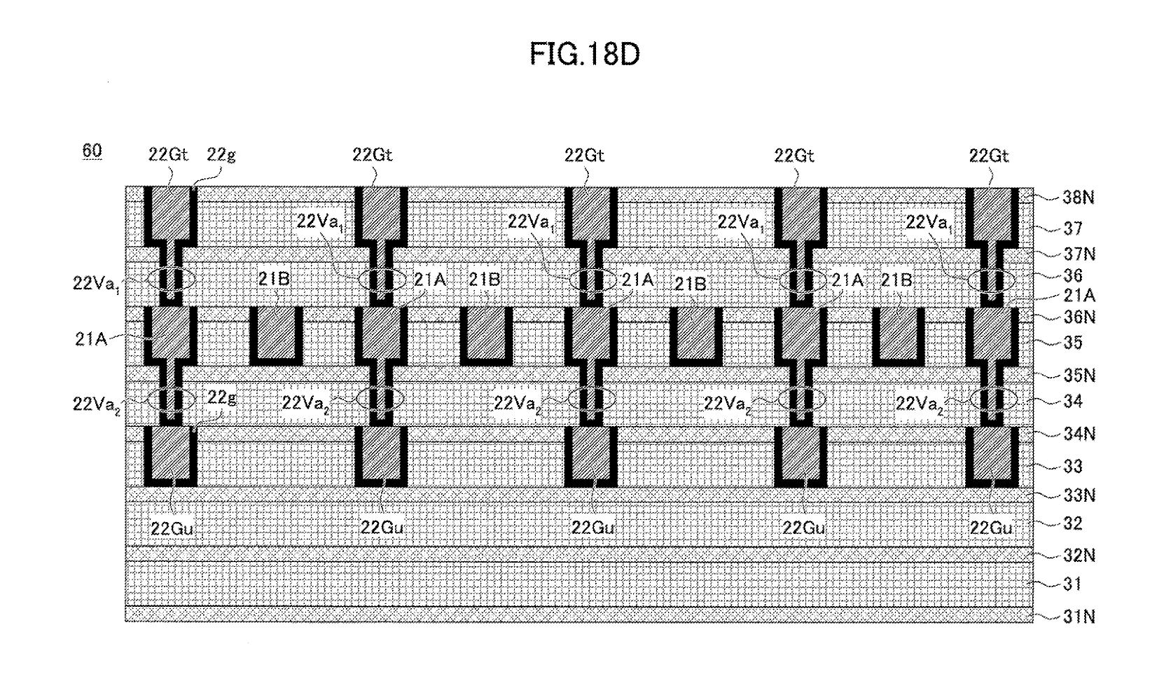

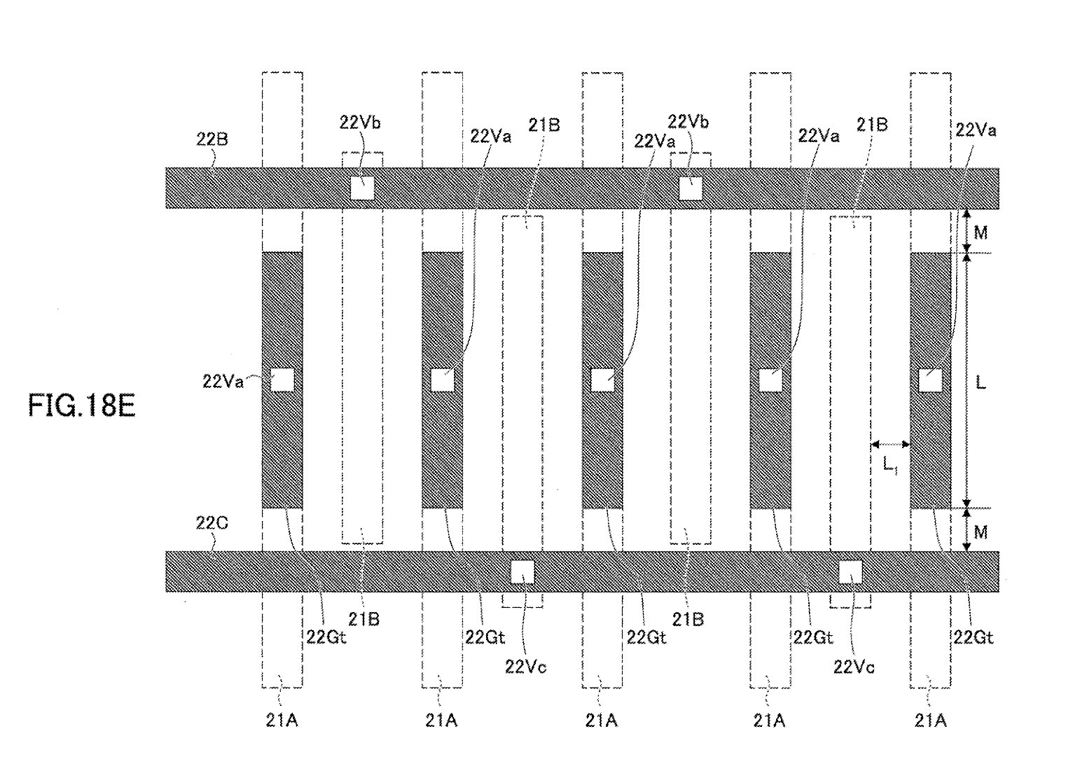

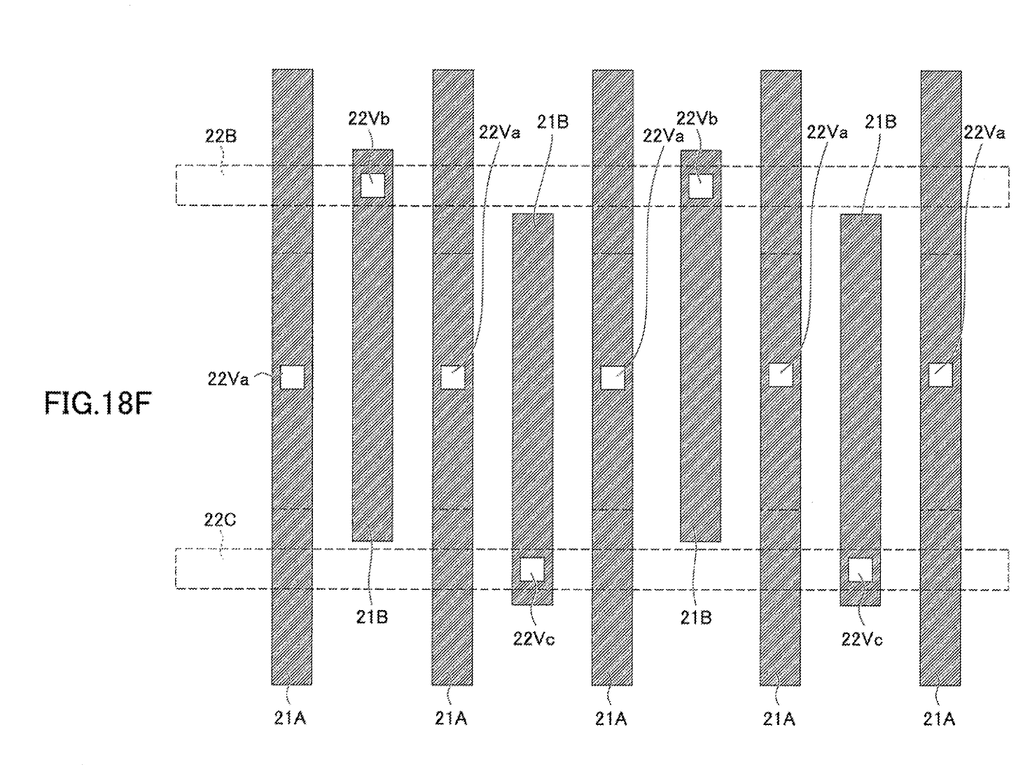

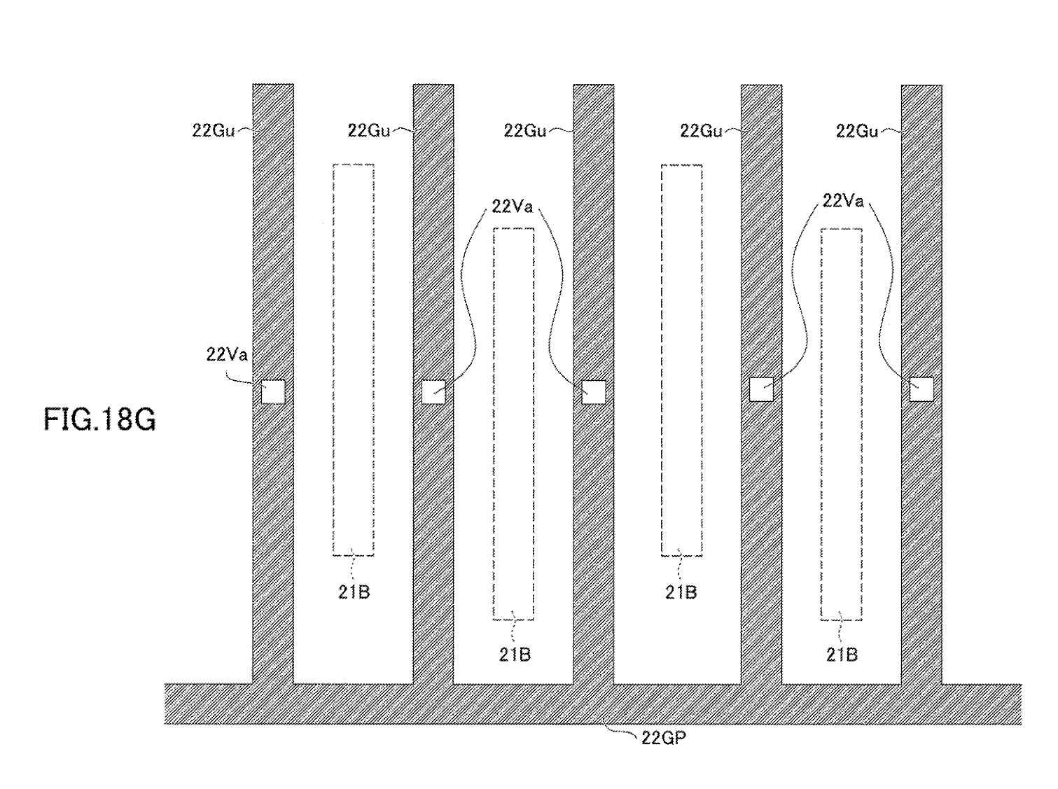

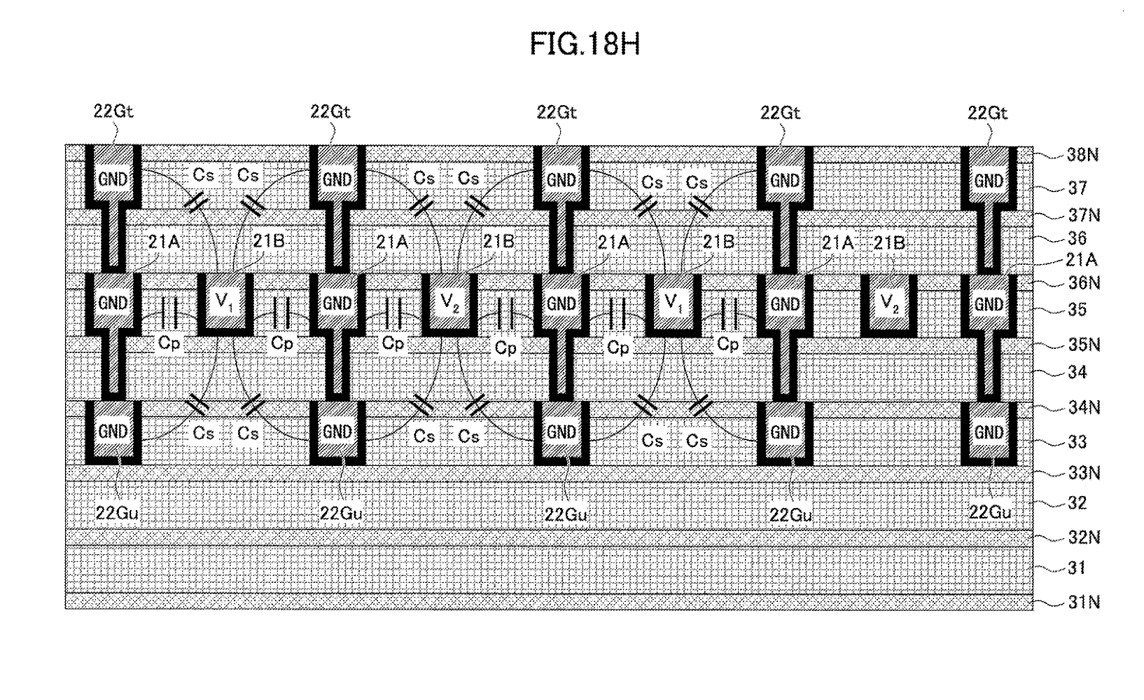

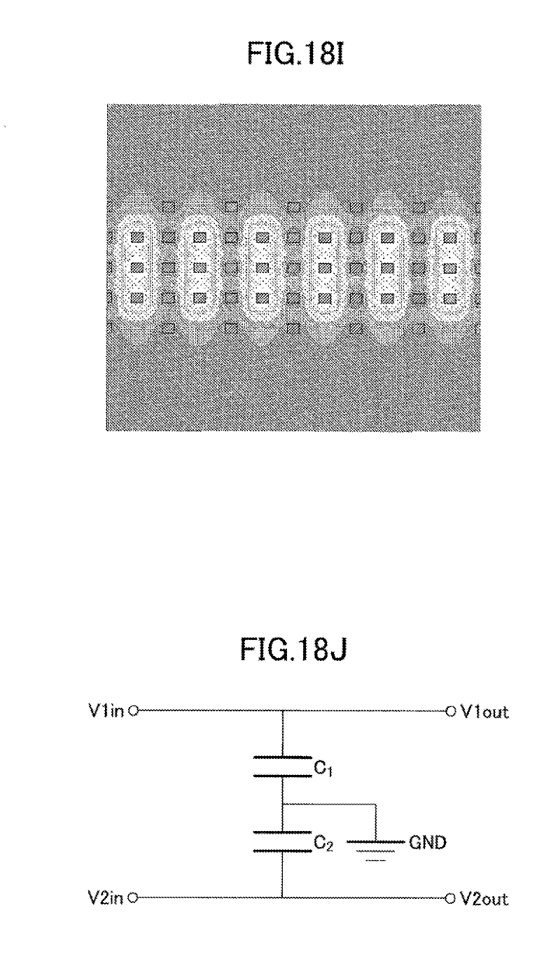

FIGS. 18A-18G represent the construction of an MIM capacitor 60 according to a sixth embodiment. Therein, FIG. 18A represents the plan view diagram of the MIM capacitor 60, while FIG. 18B represents a cross-sectional view taken along a line A-A′ of FIG. 18A, FIG. 18C represent a cross-sectional view taken along a line B-B′ of FIG. 18A, and FIG. 18D represents a cross-sectional view taken along a line C-C′ of FIG. 18A In the drawings, those parts explained before are designated by the same reference numerals and the description thereof will be omitted.

Referring to the plan view diagram of FIG. 18A, the MIM capacitor 60 includes an array of the straight electrode patterns 21A and 21B of the same length shifted alternately in the elongating directions thereof similarly to those explained with reference to FIGS. 12 and 13, wherein the wiring pattern 22B is connected to those electrode patterns 21B that are shifted in one direction by via-plugs 22Vb while skipping one electrode pattern in every two electrode patterns, and the wiring pattern 22C is connected to the rest of the electrode patterns 22B by via-plugs 22Vc that are formed alternately while skipping one electrode pattern 22B in every two electrode patterns 22B.

Referring to the cross-sectional diagram of FIG. 18B, the MIM capacitor 60 is formed, similarly to the previous MIM capacitors 20-50, in the stacked structure in which the etching stopper film 31N, the interlayer insulation film 31, the etching stopper film 32N, the interlayer insulation film 32, the etching stopper film 33N, the interlayer insulation film 33, the etching stopper film 34N, the interlayer insulation film 34, the etching stopper film 35N, the interlayer insulation film 35, the etching stopper film 36N, the interlayer insulation film 36, the etching stopper film 37N, the interlayer insulation film 37 and the etching stopper film 38N are stacked consecutively, wherein it can be seen that the wiring pattern 22B having the via-plugs 22Vb is formed in the interlayer insulation film 37 in the A-A′ cross-section by a dual damascene process as a part of the uppermost wiring layer. The via-plugs 22Vb make a contact with the surface of the electrode patterns 21B right underneath thereof, and it can be seen that there are further formed ground patterns 22Gu supplied with a fixed voltage such as the ground voltage in the interlayer insulation film 33 located under the electrode patterns 21A and 21B in correspondence to the electrode patterns 21A as a part of the lowermost wiring layer. It should be noted that the electrode patterns 21A and 21B form a part of the wiring layer intermediate between the foregoing uppermost wiring layer and the lowermost wiring layer.

Further, referring to the cross-sectional diagram of FIG. 18C representing the B-B′ cross-section, it can be seen that there is formed a wiring pattern 22C having via-plugs 22Vc in the interlayer insulation film 37 by a dual damascene process. The via-plugs 22Vc are contacted to the surface of the electrode patterns 21B right underneath thereof, wherein it can be seen also in the B-B′ cross-section that the ground patterns 22Gu are formed in the interlayer insulation film 22 in correspondence to the electrode patterns 21A.

Further, referring to the cross-sectional diagram of FIG. 18D representing the C-C′ cross-section, it can be seen also that there are formed ground patterns 22Gt supplied with a fixed voltage such as a ground voltage similarly to the ground patterns 22Gu in the interlayer insulation film 37 in correspondence to the electrode patterns 21A located underneath. It should be noted that the each of the ground patterns 22Gt has a via-plug 22Va₁ extending downward through the interlayer insulation film 36 located underneath, wherein the via-plug 22Va₁ is contacted to the surface of the corresponding electrode pattern 21A. On the other hand, each of the electrode patterns 21A is formed with a via-plug 22Va₂ extending through the interlayer insulation film 34 underneath by a dual damascene process, wherein the via-plug 22Va₂ makes a contact with the surface of the ground pattern 22Gu in the interlayer insulation film 33.

In the present embodiment, the ground patterns 22Gt and 22Gu are formed typically of copper similarly to the electrode patterns 21, 21B and the wiring patterns 22A, 22B and have the construction to fill the trenches formed in the respective interlayer insulation films via a barrier metal film 22g of the Ti/TiN structure or Ta/TaN structure.

FIG. 18E is the plan view diagram, among the various plan view diagrams of the MIM capacitor 60 of FIG. 18A, that represents the wiring patterns 22B and 22C and the ground pattern 22Gt formed in the uppermost interlayer insulation film 37. In FIG. 18E, it should be noted that the patterns at the lower levels are represented by a broken line.

Referring to FIG. 18E, it can be seen that each of the ground patterns 22Gt extends over and along the electrode pattern 21A located underneath with a length L, and it can be seen also that the ground pattern 22Gt is separated from the wiring pattern 22B or 22C with a distance M on the same plane. Here, the distance M is preferably set to be longer than the separation L₁ between the electrode patterns 21A and 21B (M>L₁) such that the ground pattern 22Gt does not form a parasitic capacitance with regard to the wiring pattern 22B or 22C.

FIG. 18F is a plan view diagram representing the array of the electrode patterns 21A and 21B. From FIG. 18F, it can be seen that the array of the electrode patterns 21A and 21B of the present embodiment is basically the same as that of FIG. 14.

FIG. 18G is a plan view diagram representing the array of the ground pattern 22Gu.

Referring to FIG. 18G, the ground patterns 22Gu extend parallel with each other and constitutes a comb-shaped pattern by being connected to a common ground pattern 22GP, wherein it should be noted that there is formed no electrode pattern 21A or 21B constituting the capacitor 60 in the plane where the ground pattern 22Gu is formed. Thus, even when there is caused optical proximity effect at the time of the photolithographic process in the connection part of the ground pattern 22Gu and the ground pattern 22GP and degradation is caused the pattern precision, there occurs no such a problem that the precision of the MIM capacitor is affected.

With the MIM capacitor of the present embodiment, it becomes possible to shield the capacitor 60 having the MIM electrodes 21A and 21B electrostatically by disposing the ground patterns 22Gt and 22Gu above and below the electrode patterns 21A and 21B as depicted in FIG. 18H.

Referring to FIG. 18H, there is formed the predetermined capacitance Cp between the electrode patterns 21B and 21A in the case a voltage V₁ is supplied to the wiring pattern 22B and the voltage V₂ is supplied to the wiring pattern 22C, wherein it should be noted that, in such a case, the lines of electric force exited from the electrode patterns 21B are terminated by the ground patterns 22Gt or 22Gu located above or below, and there occurs no extension of the lines of electric force above or below beyond the ground patterns 22Gt and 22Gu. Thus, although there may be occurrence of trifle or ignorable parasitic capacitance Cs between the electrode patterns 22B and the ground patterns 22Gt or between the electrode patterns 22B and the ground patterns 22Gu, the MIM capacitor 60 is electrostatically shielded from the outside electric field.

FIG. 18I shows the result of the simulation for verifying the shielding effect of the MIM capacitor 60.

Referring to FIG. 18I representing the simulation for a model structure that uses the electrode patterns 21A and 21B stacked one above the other in three layers, it can be seen that there is caused no spread of the electric field beyond the upper ground pattern 22Gt or lower ground pattern 22Gu. In FIG. 18I, the bright part represents the region of high potential and the dark part represents the region of low potential.

FIG. 18J represents an equivalent circuit diagram of the MIM capacitor 60 of the present embodiment.

Referring to FIG. 18J, there is supplied a voltage V₁ᵢₙ to the wiring pattern 22B and a voltage V₂ᵢₙ is supplied to the wiring pattern 22C, and there is formed a predetermined capacitance C₁ between the electrode pattern 21B connected to the wiring pattern 22B and the electrode pattern 21A adjacent thereto on the same plane. Further, there is formed a predetermined capacitance C₂ between the electrode pattern 21B connected to the wiring pattern 22C and the electrode pattern 21A adjacent thereto on the same plane. Further, the electrode pattern 21A is connected to the ground potential GND via the ground pattern 22Gu and the ground pattern 22GP. Such an MIM capacitor 60 can be used for example to a low-pass filter. In the present embodiment, it is possible to suppress the occurrence of crosstalk of the signals on the wiring 22B and the signals on the wiring 22C in the MIM capacitor 60 by forming the ground patterns 22Gt and 22Gu.

Further, an equivalent circuit similar to that of FIG. 18J can be obtained with the previous embodiments of FIGS. 11 and 13 or in the seventh embodiment to be described later.

In the present embodiment, it is obvious that the ground pattern 22Gt can be formed in the interlayer insulation film 33 and the ground pattern 22Gu is formed in the interlayer insulation film 37.

### Seventh Embodiment

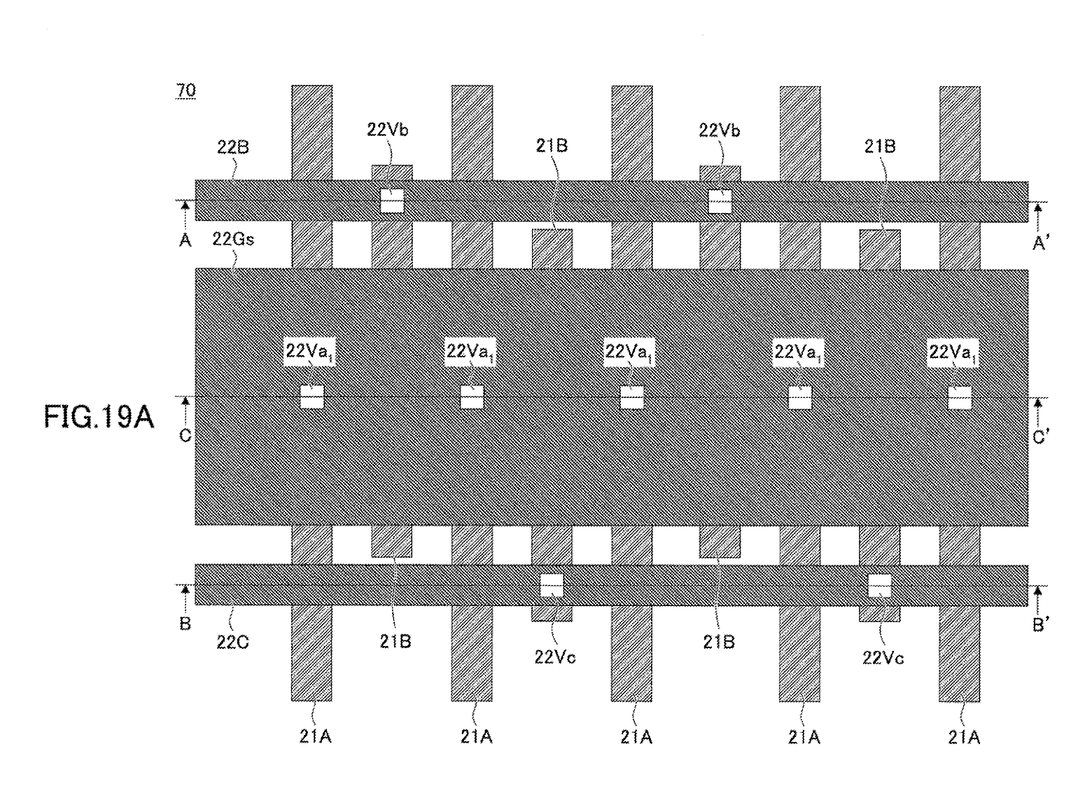

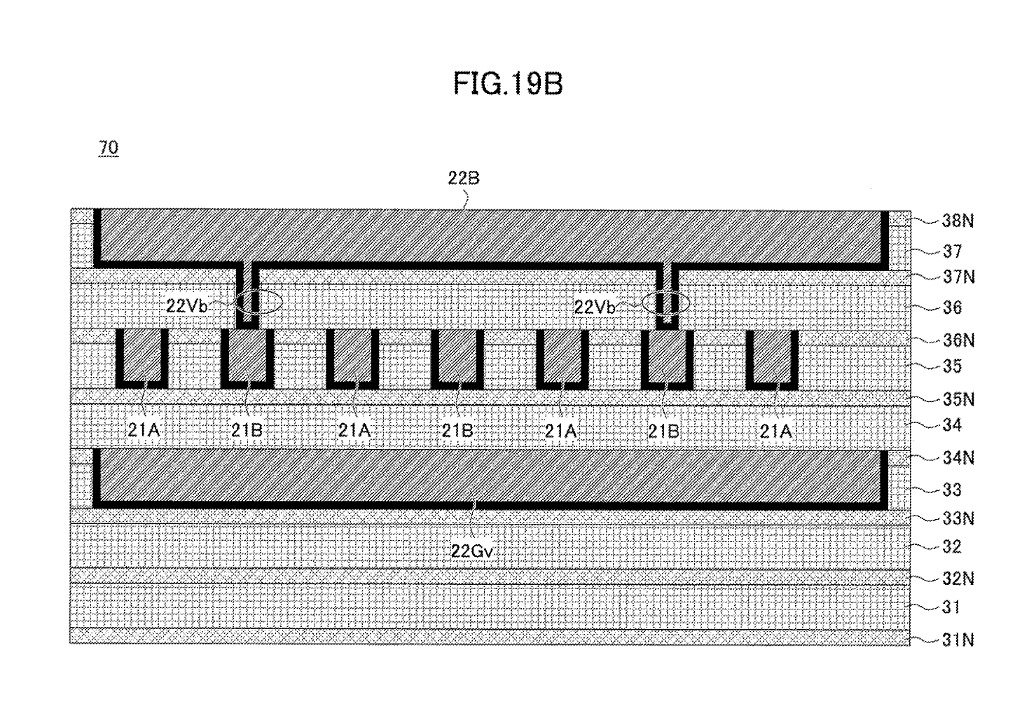

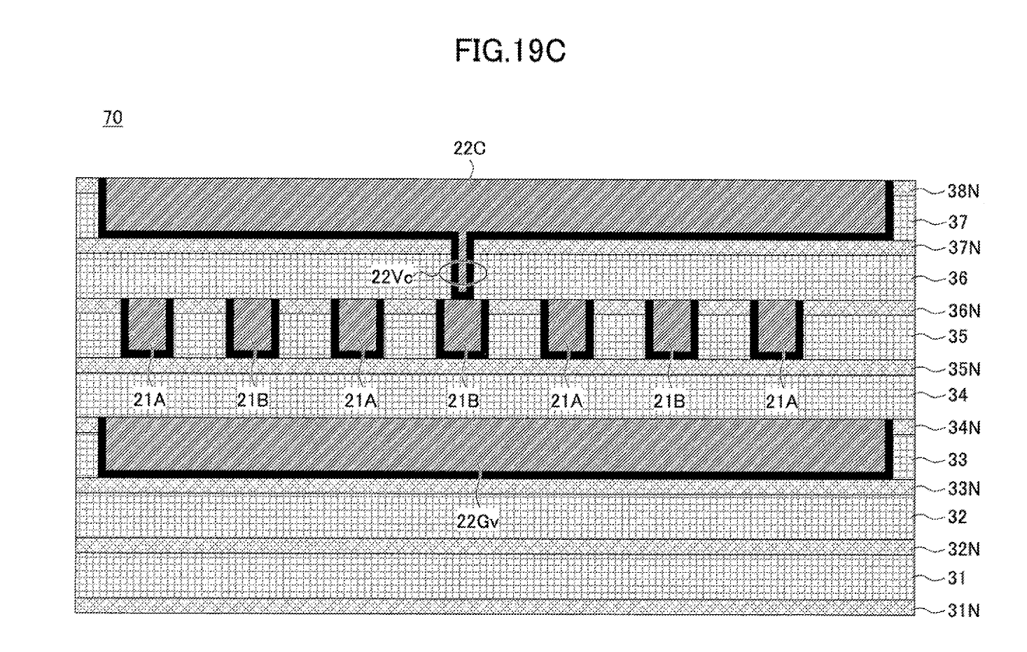

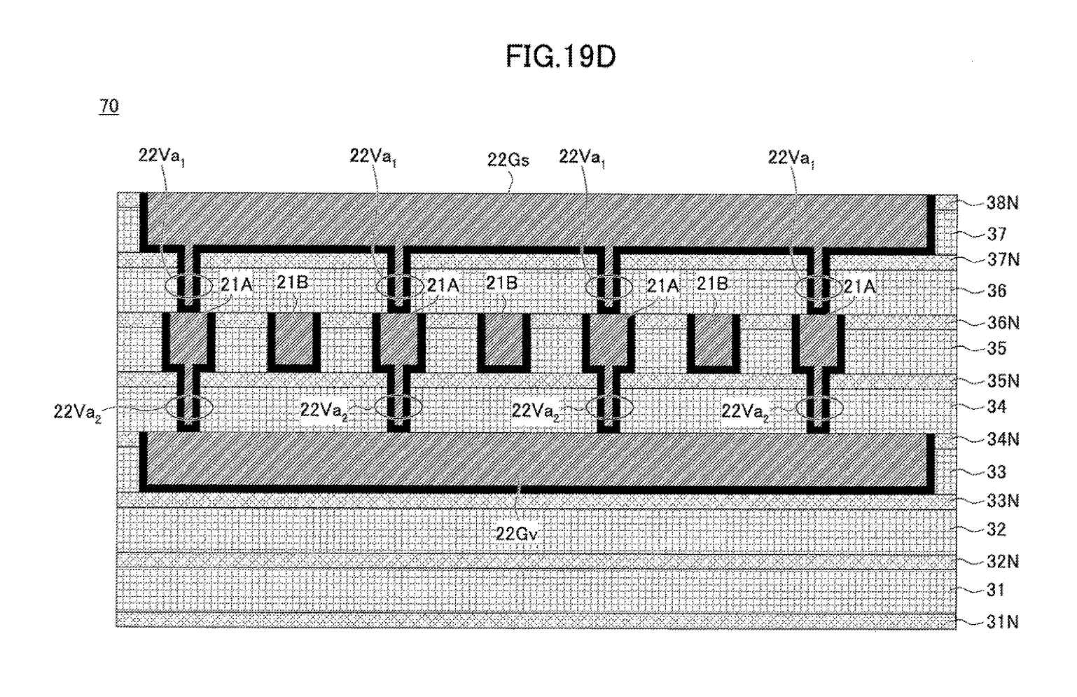

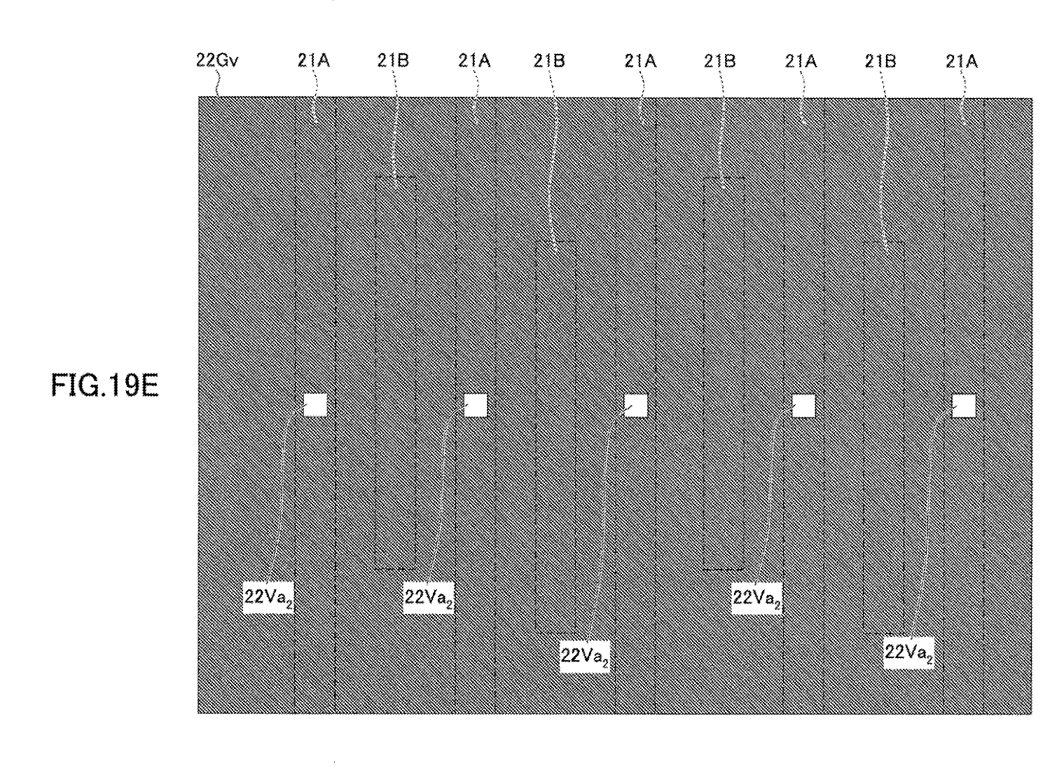

FIGS. 19A-19E represent the construction of an MIM capacitor 70 according to a seventh embodiment. Therein, FIG. 19A represents the plan view diagram of the MIM capacitor 70, while FIG. 19B represents a cross-sectional view taken along a line A-A′ of FIG. 19A, FIG. 19C represent a cross-sectional view taken along a line B-B′ of FIG. 19A, and FIG. 19D represents a cross-sectional view taken along a line C-C′ of FIG. 19A Further, FIG. 19E is a plan view diagram representing the lowermost layer of the MIM capacitor 70. In the drawings, those parts explained before are designated by the same reference numerals and the description thereof will be omitted.

Referring to the plan view diagram of FIG. 19A, the MIM capacitor 70 includes an array of the straight electrode patterns 21A and 21B of the same length shifted alternately in the elongating directions thereof similarly to those explained with reference to FIGS. 18A-18I, wherein the wiring pattern 22B is connected electrically to those electrode patterns 21B that are shifted in one direction by the via-plugs 22Vb while skipping one electrode pattern 21B in every two electrode patterns 21B, and the wiring pattern 22C is connected to the rest of the electrode patterns 22B electrically by the via-plugs 22Vc that are formed alternately while skipping one electrode pattern 21B in every two electrode patterns 21B.

Further, in the plan view diagram of FIG. 19A, it can be seen that there extends a ground pattern 22Gs between the electrode patterns 22B and 22C continuously and in parallel thereto in place of the ground patterns 22Gt of the plan view of FIG. 19A.

Referring to the cross-sectional diagram of FIG. 19B, the MIM capacitor 70 is formed, similarly to the previous MIM capacitors 60, in the stacked structure in which the etching stopper film 31N, the interlayer insulation film 31, the etching stopper film 32N, the interlayer insulation film 32, the etching stopper film 33N, the interlayer insulation film 33, the etching stopper film 34N, the interlayer insulation film 34, the etching stopper film 35N, the interlayer insulation film 35, the etching stopper film 36N, the interlayer insulation film 36, the etching stopper film 37N, the interlayer insulation film 37 and the etching stopper film 38N are stacked consecutively, wherein it can be seen that the wiring pattern 22B having the via-plugs 22Vb is formed in the interlayer insulation film 37 in the A-A′ cross-section by a dual damascene process. The via-plugs 22Vb make a contact with the surface of the electrode patterns 21B right underneath thereof, and it can be seen that there are further formed a ground pattern 22Gv supplied with a fixed voltage such as the ground voltage in the interlayer insulation film 33 located under the electrode patterns 21A and 21B continuously in correspondence to the electrode patterns 21A.

Further, referring to the cross-sectional diagram of FIG. 19C representing the B-B′ cross-section, it can be seen that the wiring pattern 22C is formed in the interlayer insulation film 37 with the via-plug 22Vc by a dual damascene process. The via-plug 22Vc is contacted to the surface of the electrode pattern 21B right underneath thereof, wherein it can be seen also in the B-B′ cross-section that the ground pattern 22Gv is formed in the interlayer insulation film 33 in correspondence to the electrode patterns 21A.

Further, referring to the cross-sectional diagram of FIG. 19D representing the C-C′ cross-section, it can be seen that the ground pattern 22Gs supplied with a fixed voltage such as a ground voltage similarly to the ground patterns 22Gv is formed in the interlayer insulation film 37 so as to cover the electrode patterns 21A and 21B located underneath continuously. It should be noted that the ground patterns 22Gs has the via-plugs 22Va₁ formed by a dual damascene process and extending downward through the interlayer insulation film 36 located underneath, wherein the via-plugs 22Va₁ are contacted to the surface of the corresponding electrode patterns 21A. On the other hand, each of the electrode patterns 21A is formed with a via-plug 22Va₂ extending through the interlayer insulation film 34 underneath by a dual damascene process, wherein the via-plug 22Va₂ makes a contact with the surface of the ground pattern 22G v in the interlayer insulation film 33.

In the present embodiment, the ground patterns 22Gs and 22Gv are formed typically of copper similarly to the electrode patterns 21, 21B and the wiring patterns 22A, 22B and have the construction to fill the trenches formed in the respective interlayer insulation films via a barrier metal film 22g of the Ti/TiN structure or Ta/TaN structure.

FIG. 19E is a plan view diagram representing the ground pattern 22Gv.

Referring to FIG. 19E, the ground pattern 22Gv is formed over the entire area where the MIM capacitor 70 is formed and is connected to a ground wiring pattern not illustrated.

With the MIM capacitor 70 of the present embodiment, too, it is possible to shield the capacitor 70 formed of the MIM electrodes 21A and 21B electrostatically and completely by disposing the ground patterns 22Gs and 22Gv respectively above and below the electrode patterns 21A and 21B, and more complete suppression of the crosstalk between the signals on the wiring pattern 22B and the signals on the wiring pattern 22C is attained.

In the present embodiment, too, it is obvious that the ground pattern 22Gv may be formed in the wiring layer 37 and the ground pattern 22Gs may be formed in the interlayer insulation film 33.

### Eighth Embodiment

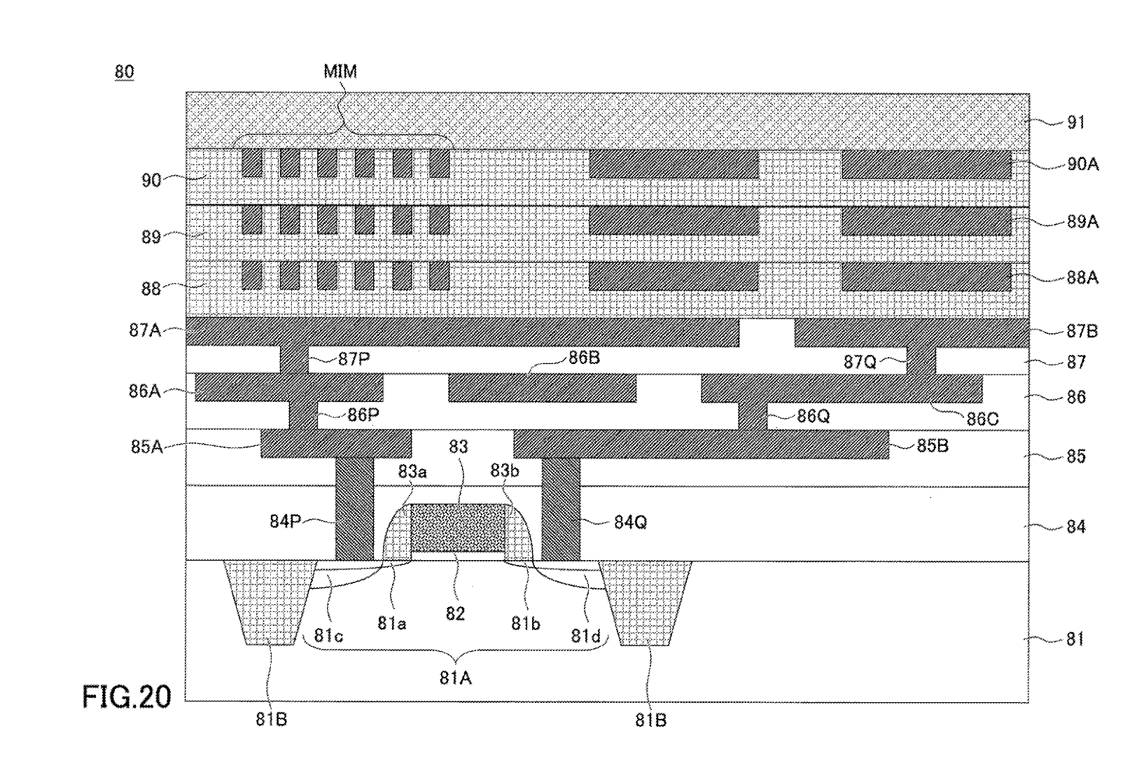

FIG. 20 is a schematic diagram representing the construction of a semiconductor device 80 according to an eighth embodiment.

Referring to FIG. 20, the semiconductor device 80 is formed in correspondence to a device region 81A defined in a silicon substrate 81 with a device isolation structure 81B and includes a gate electrode 83 formed on the silicon substrate 81 via a gate insulation film 82, wherein there are formed a source extension region 81a and a drain extension region 81b in the silicon substrate 81 in correspondence to the device region 81A at respective sides of the gate electrode 83.

The gate electrode 83 has sidewall surfaces covered with sidewall insulation films 83a and 83b, and there are formed a source region 81c and a drain region 81d in the silicon substrate at respective outer sides of the sidewall insulation films 83a and 83b in partial superposition with the source extension region 81a and the drain extension region 81b, respectively.

On the silicon substrate 81, there is formed an interlayer insulation film 84 of SiO₂, SiON, and the like, so as to cover the gate electrode 83 and the sidewall insulation films 83a and 83b, and a low-dielectric (so-called low-K) interlayer insulation film 85, typically the one marketed from The Dow Chemical Company under the trademark SiLK is formed on the interlayer insulation film 84. Further, copper wiring patterns 85A and 85B are formed in the interlayer insulation film 85. The Cu wiring patterns 85A and 85B are connected respectively to the diffusion regions 81a and 81b via contact plugs 84P and 84Q formed in the interlayer insulation film 84.

The Cu wiring patterns 85A and 85B are covered with another low-K insulation film 86 formed on the interlayer insulation film 85, and a further low-K insulation film 87 is formed on the interlayer insulation film 86.

In the illustrated example, there are embedded Cu wiring patterns 86A-86C in the interlayer insulation film 86 and there are further embedded Cu wiring patterns 87B also in the interlayer insulation film 87, wherein the wiring patterns 86A and 86C are connected to the wiring patterns 85A and 85B via respective via-plugs 86P and 86Q. Further, the wiring patterns 87A and 87B are connected to the wiring patterns 86A and 86C via respective via-plugs 87P and 87Q.

Further, in the illustrated example, there are stacked SiOC interlayer insulation films 88, 899 and 90 consecutively on the interlayer insulation film 87, wherein there are embedded a wiring pattern 88A of Cu in the interlayer insulation film 88, a wiring pattern 89A of Cu in the interlayer insulation film 89, and a wiring pattern 90A of copper in the interlayer insulation film 90.

The wiring patterns 88A, 89A and 90A are connected with each other electrically by the via-plugs not illustrated, wherein the wiring pattern 88A is connected to any of the wiring patterns 87A and 87B by a via-plug not illustrated.

Further, there is formed a passivation film 91 of SiN, or the like, on the interlayer insulation film 90 so as to cover the wiring pattern 80A. Here, the interlayer insulation films 85-90 and the wiring patterns 85A, 85B, 86A-86C and 87A-90A constitute a multilayer interconnection structure together with the via-plugs 84P, 84Q, 86P and 86Q.

Such a multilayer interconnection structure is generally formed by a damascene process or dual damascene process in view of the difficulties of dry etching Cu, such that wiring trenches and via-holes are formed in the interlayer insulation film in advance, followed by filling with a conductive film such as Cu, and further followed by a chemical mechanical polishing process (CMP) removing the conductor film remaining on the surface of the interlayer insulation film.

In the present embodiment, any of the MIM capacitors 10-70 of the previous embodiments are formed in the interlayer insulation films 88-90 in integration with the semiconductor device as a part of the multilayer interconnection structure while using a part of the wiring layers constituting the wiring patterns 88A, 89A and 90A.

Thus, with the present embodiment, it is possible to integrate the miniaturized MIM capacitors into a semiconductor device.

Further, with the present embodiment, the MIM capacitors are formed in the upper interlayer insulation films 88-90 of relatively high specific dielectric constant, and it becomes possible to increase the dielectric constant for the capacitors.

### Ninth Embodiment

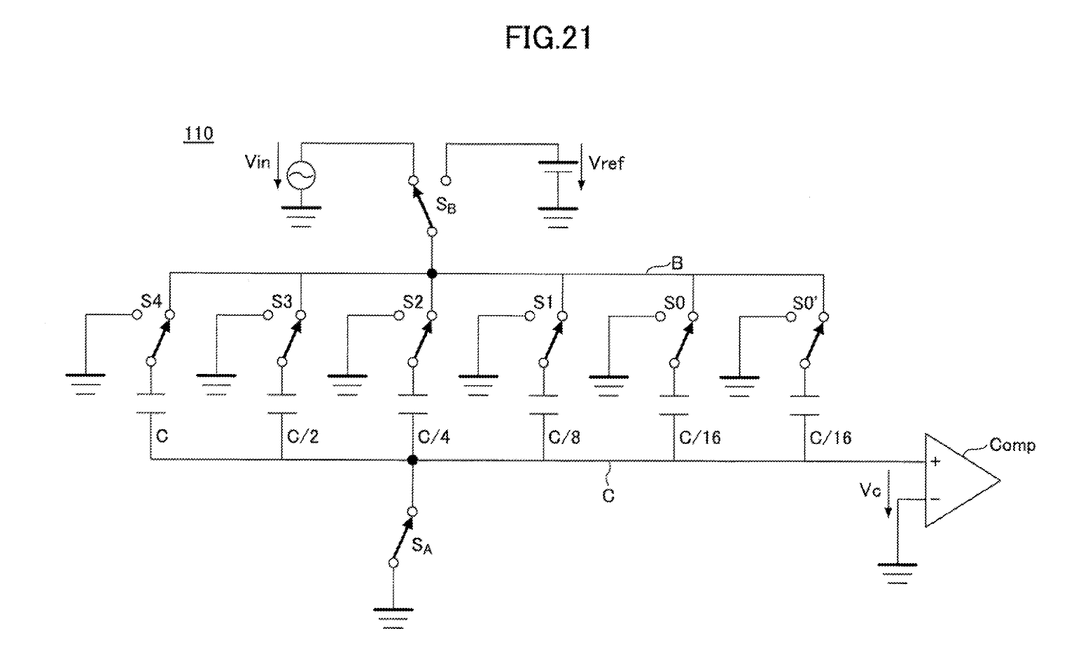

FIG. 21 represents a circuit diagram of a four-bit A/D converter 110 as an example of the circuit that is constructed by using the semiconductor device 80.

Referring to FIG. 21, the A/D converter 110 has a construction in which a number of switches S4-S0′ each formed of the transistor represented in FIG. 20 are connected commonly to a bus B, wherein the switch S4 is connected to another bus C via an MIM capacitor having the capacitance C. The bus C is connected to a +side input terminal of a comparator Comp, while it will be noted that the −side input terminal of the comparator Comp is grounded.

Further, the switch S3 is connected to the bus C via the MIM capacitor of the capacitance C/2, and the switch S2 is connected to the bus C via the MIM capacitor of the capacitance C/4. Further, the switch S1 is connected to the bus C via the MIM capacitor of the capacitance C/8, and the switch S0 is connected to the bus C via the MIM capacitor of the capacitance C/16. Further, the switch S0′ is connected to the bus C via another MIM capacitor of the capacitance C/16.

In the A/D converter 90, an input analog signal Vin or a reference voltage Vref is supplied to the bus B via the switch S_{B}, and the bus C is grounded via the switch S_{A}.

Thus, in the sampling mode, the switch S_{B} is connected to the side of the input signal Vin and the switch S_{A} connects the bus C to the ground. In this state, the respective MIM capacitors are charged by an analog voltage corresponding to the analog signals via the switches S_{B}, bus B and the switches S₄-S₀′.

Next, in the hold mode, the switch S_{B} is switched to the side of the standard voltage V_{ref}, and the switches S4-S0′ are all switched to the ground at the same time the switch S_{A} is opened. With this, the voltage Vᵢₙ held in the respective capacitors is supplied to the +side input terminal of the comparator Comp.

Further, in the conversion mode, the switches S4-S0′ are switched to the side of the bus B one by one. For example, in the case of the switch S4, there is formed a voltage dividing circuit dividing the reference voltage V_{ref} by the capacitor of the capacitance C cooperating with the switch S4 and the capacitor grounded and having the capacitance C, and an initial voltage of −Vᵢₙ+V_{ref/2} is supplied to the +side terminal of the comparator Comp. Now, in the case of Vᵢₙ>V_{ref/2}, the comparator Comp outputs the data 1 for the uppermost bit. If not, the data 0 is outputted.

Further, by switching the switches S3-S0′ consecutively in the conversion mode, there is obtained the digital data for the next bit.

With such an A/D converter, it is desirable to miniaturize the size of the individual MIM capacitors as mush as possible with the use of the integrated circuit of the construction as depicted in FIG. 20. On the other hand, it is necessary that the capacitors are formed with very high precision at lease in relative terms.

In the foregoing embodiments, it has been described heretofore that the electrode patterns and the wiring patterns are formed of copper. However, it is possible to use metals other than copper, such as aluminum, gold, tungsten, and the like, or highly doped polysilicon for the electrode patterns and the wiring patterns. In the case of using the conductive material such as aluminum, gold, tungsten or polysilicon, to which a dry etching process is applicable, it is not necessary to form the patterns by way of damascene process.

While the present invention has been explained for preferred embodiments, the present invention is not limited to such specific embodiments and various variations and modifications may be made within the scope of the invention described in patent claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A capacitor, comprising:
first electrode patterns and second electrode patterns disposed alternately on a plane, each of said first electrode patterns having a linear shape and extending in a first direction from a first end to a third end with a first length, each of said second electrodes having a linear shape and extending in said first direction from a second end to a fourth end with a second length shorter than said first length;
a first wiring pattern supplying a first voltage to said first electrode patterns by first via-plugs; and
a second wiring pattern supplying a second voltage to said second electrode patterns by second via-plugs,
said capacitor having a construction in that said first end of said first electrode pattern extends beyond said second end of said second electrode pattern in said first direction, and said third end of said first electrode pattern extends beyond said fourth end of said second electrode in a direction opposite to said first direction.

2. The capacitor claimed in claim 1, wherein said first electrode patterns and said second electrode patterns have an identical width and are disposed alternately with a space identical to said width, said first end extends beyond said second end with a distance equal to or larger than three times said space between said first and second electrode patterns.

3. The capacitor as claimed in claim 2, wherein said first end extends by a distance of 3.6 times or more of said space between said first and second electrode patterns.

4. The capacitor as claimed in claim 2, wherein said first and second electrode patterns have respective lengths in the range of 1 μm to 100 μm, and said width and said space are in the range of 10 nm to 200 nm.

5. The capacitor as claimed in claim 1, wherein said second wiring pattern supplies said second voltage to said second electrode patterns alternately via respective second via-plugs, and wherein there is provided a third wiring pattern supplying a third voltage to the rest of said second electrode patterns via respective third via-plugs.

6. The capacitor as claimed in claim 1, wherein said second electrode patterns are shifted alternately in said first direction across an intervening first electrode pattern.

7. The capacitor as claimed in claim 5, wherein said second wiring pattern is electrically connected to said second electrode patterns via respective second via-plugs formed in the vicinity of said second ends, and said third wiring pattern is electrically connected to the rest of said second electrode patterns located adjacent to said second electrode patterns connected to said second wiring pattern across an intervening first electrode pattern, via respective third via-plugs formed in the vicinity of said fourth ends, and wherein said first wiring pattern is connected to said first electrode patterns at respective central parts thereof via said first via-plugs.

8. The capacitor as claimed in claim 1, wherein said first and second electrode patterns are formed in a first wiring layer and said first and second wiring patterns are formed in a second wiring layer above or below said first wiring layer.

9. The capacitor as claimed in claim 8, wherein said first and second electrode patterns are formed in each of a plurality of wiring layers stacked each other consecutively, a first electrode pattern in one wiring layer is formed right underneath a first electrode pattern of a next wiring layer, a second electrode pattern in said one wiring layer is formed right underneath a second electrode pattern of said next wiring layer, said first electrode pattern of said one wiring layer is connected electrically to said first electrode pattern of said next wiring layer by a via-plug, and said second electrode pattern of said one wiring layer is connected electrically to said second electrode pattern of said next wiring layer by another via-plug.

10. The capacitor as claimed in claim 9, wherein said first and second wiring patterns are formed in a wiring layer above or below said plurality of wiring layers.

11. The capacitor as claimed in claim 9, wherein said first and second patterns are formed in a wiring layer above said plurality of wiring layers and in a wiring layer below said plurality of wiring layers.

12. The capacitor as claimed in claim 1, wherein said first and second electrode patterns are formed in each of a first wiring layer and a third wiring layer of a stack of wiring layers in which said first wiring layer and said third wiring layer are stacked consecutively with a second, intervening wiring layer, a first electrode pattern in said first wiring layer is formed underneath a first electrode pattern in said third wiring layer and a second electrode pattern in said first wiring layer is formed underneath a second electrode pattern in said third wiring layer, said first wiring pattern sand said second wiring pattern are formed in said second wiring layer, said first wiring pattern being connected electrically to said first electrode patterns in said first wiring layer and said first electrode patterns in said third wiring layer by respective via-plugs, said second wiring pattern being connected to said second electrode patterns in said first wiring layer and said second electrode patterns in said third wiring layer by respective via-plugs.

13. The capacitor as claimed in claim 9, wherein said first and second wiring patterns are formed in a wiring layer further above or below said plurality of wiring layers stacked consecutively, there being formed first ground patterns in said wiring layer in which said first and second wiring patterns are formed while avoiding said first and second wiring layers and in correspondence to said first electrode patterns, there being further formed second ground patterns in correspondence to said first electrode patterns in a wiring layer further below said plurality of wiring layers stacked consecutively in the case said first ground patterns are formed in the wiring layer further above said plurality of wiring layers stacked consecutively and in the wiring layer further above said plurality of wiring layers stacked consecutively in the case said first ground pattern is formed in the wiring layer further below said plurality of wiring layers stacked consecutively.

14. The capacitor as claimed in claim 13, wherein said first ground patterns extend along said first and second wiring patterns so as to cover said first and second electrode patterns and said second ground patterns extend so as to cover said first and second electrode patterns.

15. A semiconductor device having a multilayer interconnection structure, said multilayer interconnection structure including a capacitor, said capacitor comprising:
first electrode patterns and second electrode patterns disposed alternately on a plane, each of said first electrode patterns having a linear shape and extending in a first direction from a first end to a third end with a first length, each of said second electrodes having a linear shape and extending in said first direction from a second end to a fourth end with a second length shorter than said first length;
a first wiring pattern supplying a first voltage to said first electrode patterns by first via-plugs; and
a second wiring pattern supplying a second voltage to said second electrode patterns by second via-plugs,
said capacitor having a construction in that said first end of said first electrode pattern extends beyond said second end of said second electrode pattern in said first direction, and said third end of said first electrode pattern extends beyond said fourth end of said second electrode in a direction opposite to said first direction.

16. The semiconductor device as claimed in claim 15, wherein said multilayer interconnection structure comprises an upper part in which said interlayer insulation films have a first specific dielectric constant and a lower part in which said interlayer insulation films have a second specific dielectric constant lower than said first dielectric constant, and wherein said capacitor is formed in said upper part.
